(19) United States
(12) Patent Application Publication
(10) Pub. No.: US 2025/0316588 A1
(43) Pub. Date: Oct. 9, 2025

(54) SEMICONDUCTOR DEVICE

(71) Applicant: ROHM CO., LTD., Kyoto (JP)

(72) Inventors: Keiji WADA, Kyoto (JP); Koji SAITO, Kyoto (JP)

(73) Assignee: ROHM CO., LTD., Kyoto (JP)

(21) Appl. No.: 19/173,611

(22) Filed: Apr. 8, 2025

(30) Foreign Application Priority Data
Apr. 9, 2024 (JP) 2024-062842

(51) Int. Cl. H01L 23/522; H01L 23/528; H10D 1/47; H10D 1/68

(52) U.S. Cl. CPC H01L 23/5228; H01L 23/5223; H01L 23/5286; H10D 1/47; H10D 1/692

(57) ABSTRACT

A semiconductor device includes a semiconductor substrate, an insulating layer, and a resistor. The resistor includes a first resistor layer. A first embedded electrode is electrically connected to the first resistor layer. A second resistor layer is disposed adjacent to the first resistor layer and electrically connected to the first resistor layer. A second embedded electrode is electrically connected to the second resistor layer. A first supplemental electrode extends in a lengthwise direction of the first resistor layer, is electrically connected to the first embedded electrode, and has a thickness greater than a thickness of the first resistor layer. A second supplemental electrode extends in the lengthwise direction, is electrically connected to the second embedded electrode, has a thickness greater than a thickness of the second resistor layer, is adjacent to the first supplemental electrode, and constitutes a capacitor together with the first supplemental electrode.

### CROSS REFERENCE TO RELATED APPLICATION

This application is based upon and claims the benefit of priority of the prior Japanese Patent Application No. 2024-062842, filed on Apr. 9, 2024, the entire contents of which are incorporated herein by reference.

### TECHNICAL FIELD

The present disclosure relates to a semiconductor device.

### BACKGROUND ART

WO 2023/085026 discloses a semiconductor device including a plurality of resistors in a chip.

### BRIEF DESCRIPTION OF THE DRAWINGS

FIG. 1 is a plan view of a semiconductor package equipped with a high voltage detection device.

FIG. 2 is a circuit diagram of the high voltage detection device.

FIG. 3A is a circuit diagram of a first example of resistors and FIG. 3B is a circuit diagram of a second example of resistors.

FIG. 4 is a circuit diagram of resistors including a high resistance unit.

FIG. 5 is a plan view of the resistors including the high resistance unit.

FIG. 6A is a vertical cross-sectional view of a resistor shown in FIG. 5 along the arrow A-A, FIG. 6B is vertical cross-sectional view of a resistor shown in FIG. 5 along the arrow B-B, and FIG. 6C is a vertical cross-sectional view of a resistor shown in FIG. 5 along the arrow C-C.

FIG. 7 is a circuit diagram of resistors including a high resistance unit.

FIG. 8 is a plan view of the resistors including the high resistance unit.

FIG. 9A is a vertical cross-sectional view of a resistor shown in FIG. 8 along the arrow A-A, FIG. 9B is vertical cross-sectional view of a resistor shown in FIG. 8 along the arrow B-B, and FIG. 9C is a vertical cross-sectional view of a resistor shown in FIG. 8 along the arrow C-C.

FIG. 10 is a perspective view of an edge structure including supplemental electrodes and a resistor layer.

FIG. 11 is a plan view of the resistors including the high resistance unit.

FIG. 12A is a vertical cross-sectional view of a resistor shown in FIG. 11 along the arrow A-A, FIG. 12B is vertical cross-sectional view of a resistor shown in FIG. 11 along the arrow B-B, and FIG. 12C is a vertical cross-sectional view of a resistor shown in FIG. 11 along the arrow C-C.

FIG. 13 is a plan view of the resistors including the high resistance unit.

FIG. 14A is a vertical cross-sectional view of a resistor shown in FIG. 13 along the arrow A-A, FIG. 14B is vertical cross-sectional view of a resistor shown in FIG. 13 along the arrow B-B, and FIG. 14C is a vertical cross-sectional view of a resistor shown in FIG. 13 along the arrow C-C.

FIG. 15 is a plan view of the resistors including the high resistance unit.

FIG. 16A is a vertical cross-sectional view of a resistor shown in FIG. 15 along the arrow A-A, FIG. 16B is vertical cross-sectional view of a resistor shown in FIG. 15 along the arrow B-B, and FIG. 16C is a vertical cross-sectional view of a resistor shown in FIG. 15 along the arrow C-C.

FIG. 17 is a perspective view of an edge structure including supplemental electrodes and a resistor layer.

FIG. 18 is a plan view of the resistors including the high resistance unit.

FIG. 19A is a vertical cross-sectional view of a resistor shown in FIG. 18 along the arrow A-A, FIG. 19B is vertical cross-sectional view of a resistor shown in FIG. 18 along the arrow B-B, and FIG. 19C is a vertical cross-sectional view of a resistor shown in FIG. 18 along the arrow C-C.

FIG. 20 is a plan view of a resistor chip according to one example.

FIGS. 21A, 21B, and 21C are plan views of low resistance units for voltage detection.

### DETAILED DESCRIPTION OF EMBODIMENTS

Below, various exemplary embodiments will be described in detail with reference to the drawings. The same or corresponding components in the drawings are assigned the same reference characters and redundant explanations thereof will be omitted.

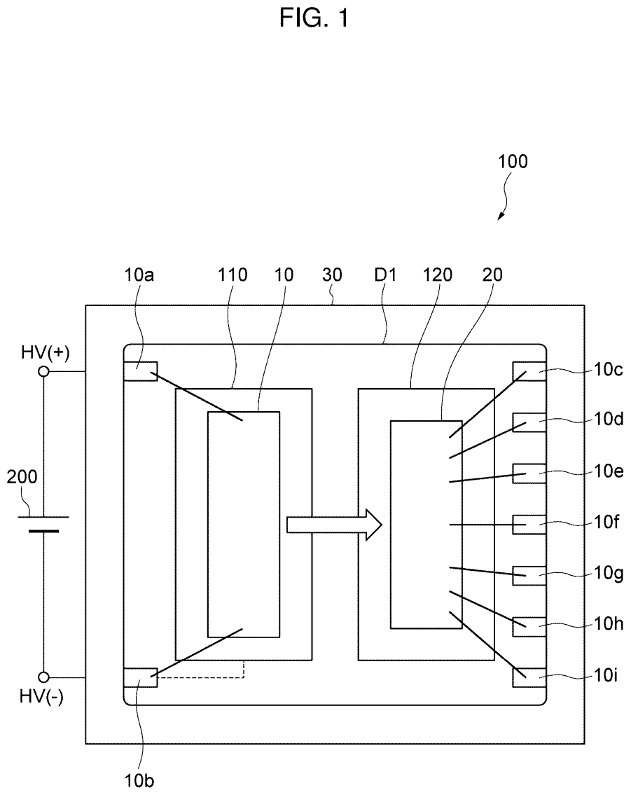

FIG. 1 is a plan view of a semiconductor package 100 equipped with a high voltage detection device. FIG. 1 shows a state in which a top lid is removed.

The semiconductor package 100 comprises a case 30 having a recess D1. The case 30 is made of an insulating material such as a resin or a ceramic. The semiconductor package 100 includes a resistor chip 10 (semiconductor device) disposed on a first die pad 110 in the recess D1, and an amplifier chip 20 (semiconductor device) disposed on a second die pad 120 in the recess D1. An open edge of the recess D1 of the semiconductor package 100 is sealed with a lid (not shown), and therefore, the inside of the recess D1 is a closed off space. The lid can be made of an insulating material such as a resin, and the inside of the recess D1 may be filled with a gas or with an insulating material. The first die pad 110 and the second die pad 120 have applied thereto a suitable potential such as ground potential via a lead frame. Also, the potential of the first die pad 110 may be set high as necessary, for example.

The output voltage of the resistor chip 10 is inputted to the amplifier chip 20. The amplifier chip 20 outputs an output voltage based on the detected voltage.

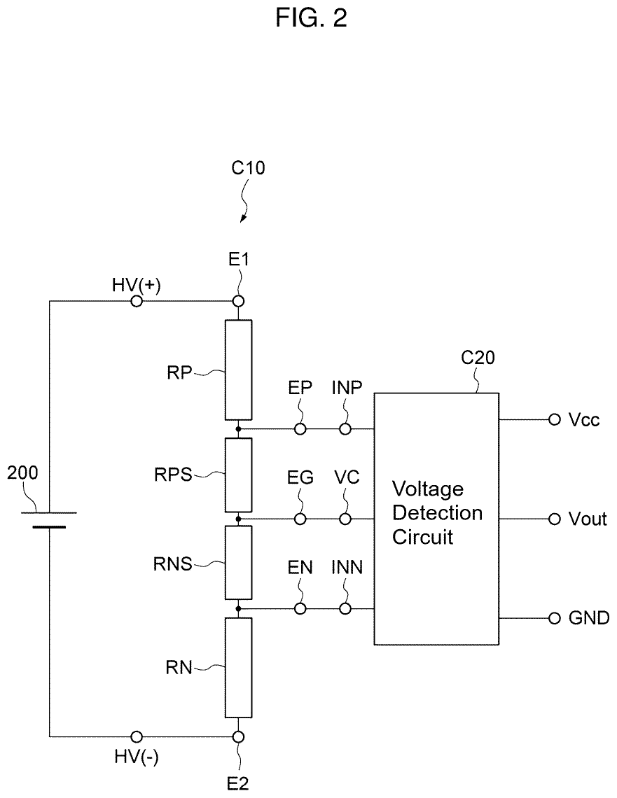

The positive electrode terminal of a battery 200 is electrically connected to a first inner lead 10a, and is connected to a first electrode E1 (see FIG. 2) of the resistor chip 10 via a bonding wire. The negative electrode terminal of the battery 200 is electrically connected to a second inner lead 10b, and is connected to a second electrode E2 (see FIG. 2) of the resistor chip 10 via a bonding wire.

Each terminal of the amplifier chip 20 can be connected, via a bonding wire, to a third inner lead 10c, a fourth inner lead 10d, a fifth inner lead 10e, a sixth inner lead 10f, a seventh inner lead 10g, an eighth inner lead 10h, and a ninth inner lead 10i.

For example, a power source voltage Vcc is applied to the third inner lead 10c and inputted to the amplifier chip 20. A ground potential GND is applied to the ninth inner lead 10i and inputted to the amplifier chip 20. The sixth inner lead 10f can output an output voltage Vout. A monitor signal based on the potential of a first output electrode EP (see FIG. 2) can be outputted from the fourth inner lead 10d. A monitor signal based on the potential of a second output electrode EN (see FIG. 2) can be outputted from the eighth inner lead 10h. The fifth inner lead 10e and the seventh inner lead 10g can be used for other applications as necessary.

FIG. 2 is a circuit diagram of the high voltage detection device. The high voltage detection device includes a resistor circuit C10 (voltage-dividing circuit) and a voltage detection circuit C20. The resistor chip 10 includes the resistor circuit C10. The amplifier chip 20 includes the voltage detection circuit C20. A first input terminal HV(+) of the resistor circuit C10 is electrically connected to the positive electrode of the battery 200. A second input terminal HV (-) of the resistor circuit C10 is electrically connected to the negative electrode of the battery 200. The first input terminal HV(+) is electrically connected to the first electrode E1 (electrode pad). The second input terminal HV(−) is electrically connected to the second electrode E1 (electrode pad).

The resistor circuit C10 includes a first high resistance unit RP (first resistor), a first low resistance unit RPS, a second low resistance unit RNS, and a second high resistance unit RN (second resistor). Between the first electrode E1 and the second electrode E2, the first high resistance unit RP, the first low resistance unit RPS, the second low resistance unit RNS, and the second high resistance unit RN are connected in series in the stated order. The first high resistance unit RP and the second high resistance unit RN have the function of lowering high voltage and each have a high resistance. The first low resistance unit RPS and the second low resistance unit RNS have the function of detecting voltage and each have a lower resistance than the high resistance units.

An example of a resistance of one high resistance unit is 500 MΩ, but can be 1 MΩ to 1,000 MΩ, inclusive. The resistance of the high resistance units can also be set to 100 MΩ to 800 MΩ, inclusive. The resistance of the high resistance units can also be set to 300 MΩ to 600 MΩ, inclusive. The resistances may be set to any value that allows for durability against high voltages and that allows for voltage detection.

The resistance of one low resistance unit (RPS or RNS) is K % or less of the resistance of the high resistance units. Examples of K include 5%, 3%, 1%, 0.5%, 0.3%, 0.1%, 0.05%, or 0.01%, and the resistance of the low resistance units can be set to 0.01 MΩ to 10 MΩ, for example.

The connection point between the first high resistance unit RP and the first low resistance unit RPS is electrically connected to the first output electrode EP (electrode pad). The connection point between the second high resistance unit RN and the second low resistance unit RNS is electrically connected to the second output electrode EN (electrode pad). A reference electrode EG (electrode pad) is electrically connected between the first low resistance unit RPS and the second low resistance unit RNS.

The resistor circuit C10 is a voltage-dividing circuit, and thus, a voltage based on the resistance at two selected points in the resistor circuit C10 can be attained. The first output electrode EP is electrically connected to a first input terminal INP of the voltage detection circuit C20. The second output electrode EN is electrically connected to a second input terminal INN of the voltage detection circuit C20. The reference electrode EG is electrically connected to a reference terminal VC of the voltage detection circuit C20. The potential of the reference terminal VC can be set to ground potential, for example. The voltage detection circuit C20 can output the output voltage Vout. The output voltage Vout can be the total of: a first potential difference between the first input terminal INP and the reference terminal VC; and a second potential difference between the second input terminal INN and the reference terminal VC. The voltage detection circuit C20 can include a source follower (amplifier) that amplifies the voltage inputted from the input terminal, and can be provided with a differential amplifier circuit for attaining the total input voltage. The voltage detection circuit C20 includes an input terminal for the power source voltage Vcc for operating the internal circuit, and an input terminal for setting the ground potential GND.

The resistor circuit C10 can include a dummy resistor.

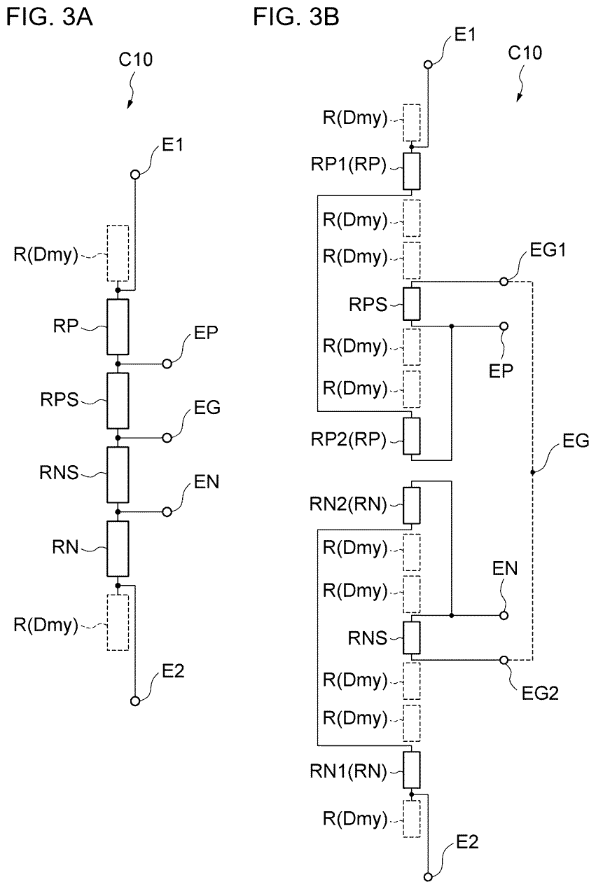

FIG. 3A is a circuit diagram of a first example of resistors and FIG. 3B is a circuit diagram of second example of resistors.

In the resistor circuit C10 of FIG. 3A, the first end of a dummy resistor R(Dmy) is electrically connected to the input side of the first high resistance unit RP. A dummy resistor R(Dmy) is electrically connected to the input side of the second high resistance unit RN.

The dummy resistor may alternatively not be electrically connected to a resistor. The resistors on both ends of the resistor chip sometimes differ in resistance characteristics compared to resistors towards the center, for example. The detection accuracy may be improved by using such resistors as dummy resistors.

The resistor circuit C10 of FIG. 3B has a configuration modified from that of the circuit of the first example. In this example, the first high resistance unit RP is constituted of a high resistance unit RP1 and a high resistance unit RP2 connected in series, and the second high resistance unit RN is constituted of a high resistance unit RN1 and a high resistance unit RN2 connected in series. Also, the reference electrode EG is separated into a first reference electrode EG1 and a second reference electrode EG2, and these electrodes are put in a state enabling electrical connection therebetween on the voltage detection circuit side. As a comparison to the circuit of the first example, one or more dummy resistors R(Dmy) are also provided between the resistors.

The dummy resistor is a resistor through which no current flows, and is provided in order to maintain electrical equivalence in the resistor circuit C10, maintain electrical stability, or reduce causes for error in manufacturing the resistor during the manufacturing process. The circuit configuration of the high voltage detection device is not limited thereto, and the shape and arrangement of the resistors may be changed as long as the basic voltage detection function can be exhibited.

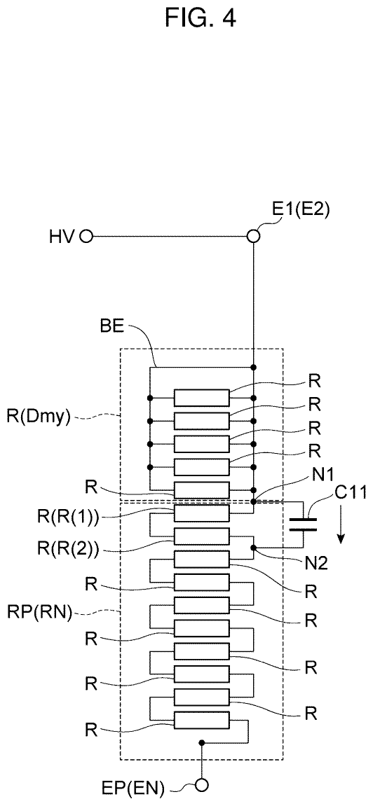

The above-mentioned high voltage detection device can be accommodated in one semiconductor package as described above. The functions of each circuit may be installed in the package so as to be distributed between the resistor chip and the amplifier chip. A modification can also be made such that some of the circuit elements are transferred to inside either of the chips, or consolidated in one chip. FIG. 4 is a circuit diagram of resistors including the high resistance unit.

The high voltage (HV) input terminal is connected to the first electrode E1 (or second electrode E2). The first electrode E1 is electrically connected to the first high resistance unit RP. The second electrode E2 is electrically connected to the second high resistance unit RN. The first high resistance unit RP (or second high resistance unit RN) includes a plurality of resistors R connected in series. A node in the first high resistance unit RP (or second high resistance unit RN) where a high voltage (high potential) is first inputted is designated as a first node N1. In the first high resistance unit RP (or second high resistance unit RN), a second node N2 of a resistor R adjacent to the resistor R connected to the first node N1 is adjacent to the first node N1.

An end of the first high resistance unit RP (or second high resistance unit RN) is electrically connected to the dummy resistor R(Dmy) (extension region). The dummy resistor R(Dmy) includes one or more resistors R. Each of the resistors R is a resistor layer, and a specific example of a plan view shape is a linear shape that extends in a line, and thus, the resistor R can be referred to as a linear resistor or a line-shape resistor. In the dummy resistor R(Dmy) of this example, both ends of each resistor R are short-circuited, and the plurality of resistors R are connected in parallel. In this example, an embedded electrode BE (embedded wiring line) positioned at the end short-circuits both ends of the resistors R in the dummy resistor R(Dmy), but the short-circuiting may be performed by another wiring line.

The embedded electrode BE (embedded wiring line) for short-circuiting can be disposed directly below the dummy resistor R(Dmy).

If a greater voltage than ground potential is inputted to the first electrode E1 (or second electrode E2), the voltage is transmitted to the first node N1. In a normal state, the potential of the first node N1 undergoes a voltage drop via the one or more resistors R connected in series, and the potential after the voltage drop appears in the second node N2. If the potential of the first node N1 instantaneously increases, the potential of the second node N2 cannot immediately follow this change, and thus, a large potential difference occurs between the first node N1 and the second node N2.

If, for example, the gap between a first resistor R (R(1)) having the first node N1 as the first end thereof and a second resistor R (R(2)) having the second node N2 is 1 μm, then if a voltage (e.g., 4,000V) exceeding a voltage (e.g., 500V) that applies the maximum electric field that can be withstood by the gap is applied between the first node N1 and the second node N2, then damage can occur.

In this example, a first capacitor C11 is connected between the first node N1 and the second node N2.

If the potential of the first node N1 undergoes a rapid increase, a current flows to the first capacitor C11, which increases the potential of the second node N2. Thus, by reducing the potential difference between the first node N1 and the second node N2, damage in the vicinity of a node where a rapid change in voltage occurs can be mitigated.

It is preferable that the capacitance of the exemplary first capacitor C11 or a combined capacitance be at least 1 fF and, if possible, greater than or equal to 10 fF. Such a range is considered to sufficiently mitigate rapid voltage changes.

If the potential of the second node N2 were to rapidly increase, a potential difference could also occur at the node between the second node N2 and an adjacent resistor R on the low potential side, and damage can occur from such a potential difference. Thus, it is preferable that a plurality of capacitors be electrically connected between the ends of the resistors R.

The first capacitor C11 can be constituted of a first supplemental electrode electrically connected to the first node N1 and a second supplemental electrode electrically connected to the second node N2. Details will be explained below.

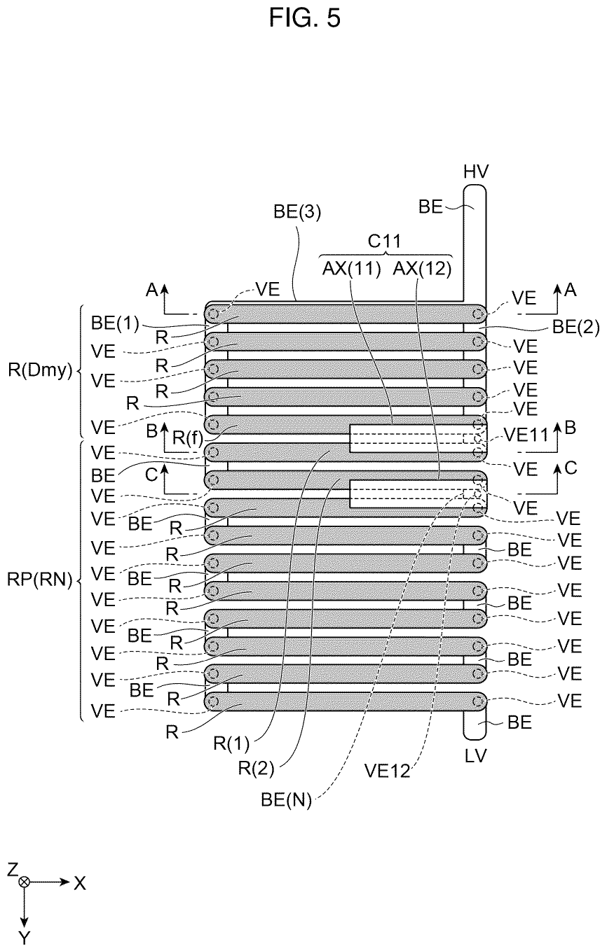

FIG. 5 is a plan view of the resistors including the high resistance unit shown in FIG. 4. The resistors, the embedded electrodes, and the supplemental electrodes are, in reality, embedded in an insulating layer, but for ease of explanation, the insulating layer is not shown.

Each of the resistors R extends in the X axis direction, and the plurality of resistors R are arrayed in the Y axis direction. The depth direction of the chip is the Z axis, and the Z axis is perpendicular to the X axis and the Y axis. A via electrode VE is physically and electrically connected to the bottom surface of both ends of each of the resistors R, and the via electrode VE is physically and electrically connected to the embedded electrode BE. The physical connection of conductive elements results in an electrical connection, and thus, if the elements are clearly in a connected state, this state is sometimes referred to with the word “connection” or “connected.”

In the dummy resistor R(Dmy), the embedded electrode BE includes a first connection region BE(1) to which all first ends of the plurality of resistors R are connected, a second connection region BE(2) to which all second ends are connected, and a third connection region BE(3) that connects the foregoing connection regions. The third connection region BE(3) is disposed directly below the resistor positioned at an end in the chip length direction.

In the first high resistance unit RP (or second high resistance unit RN), the embedded electrodes BE connect the first ends of the nth and (n+1)th resistors R as counted from the high voltage (HV) side in the Y axis direction, and connect the second ends of the (n+1)th and (n+2)th resistors R(n being a natural number, and typically an odd number).

In one possible structure, the vertical positional relationship between the resistors R and the via electrodes VE and embedded electrodes BE is reversed. In such a case, the resistors R are positioned in a lower layer than the via electrodes VE and the embedded electrodes BE.

The embedded electrode BE connected to the input-side electrode to which a high voltage (HV) is applied is connected via the via electrode VE to a first end on the input side of a first resistor layer (first resistor layer (resistor R(1))) via the embedded electrode BE (second connection region BE(2)) positioned below the first end of the dummy resistor R(Dmy).

The first end of the last resistor R(f) (last dummy resistor layer) of the dummy resistor R(Dmy) is also connected to the embedded electrode BE (second connection region BE(2)) via the via electrode VE. That is, the first end of the last resistor R(f) of the dummy resistor R(Dmy) and the first end of the first resistor layer (resistor R(1)) are both connected to the second connection region BE(2) constituting the embedded electrode. A first supplemental electrode AX(11) is disposed above the region between the last resistor R(f) and the first resistor layer (resistor R(1)). The first supplemental electrode AX(11) is electrically connected to the second connection region BE(2) via a first via electrode VE11.

The first end of a second second resistor layer (resistor R(2)) subsequent to the first second resistor layer is connected via the via electrode VE to the embedded electrode BE(N). An embedded electrode BE(N) connects the first end of the adjacent resistor R via the via electrode VE, similar to other embedded electrodes BE. The embedded electrode BE(N) is connected via a second via electrode VE12 to a second supplemental electrode AX(12) positioned thereabove.

The first supplemental electrode AX(11) extends in the X axis direction. The second supplemental electrode AX(12) extends in the X axis direction. The first supplemental electrode AX(11) and the second supplemental electrode AX(12) are adjacent to each other in the Y axis direction and a gap is present therebetween. In this gap, a dielectric constituting a protective layer or an insulating layer is placed. Thus, the first supplemental electrode AX(11) and the second supplemental electrode AX(12) constitute a capacitor. The thickness of the first supplemental electrode AX(11) is greater than the thickness of the first resistor layer (resistor R(1)). The thickness of the first supplemental electrode AX(12) is greater than the thickness of the second resistor layer (resistor R(2)). This is due to the fact that if the supplemental electrode is too thin, a capacitance sufficient to transmit current cannot be attained.

The plurality of resistors R in the high resistance unit are connected in series between the electrode applying the high voltage (HV) and the output electrode on the low voltage (LV) side.

In a plan view, the region where the dummy resistor R(Dmy) is disposed is the extension region extending in the lengthwise direction (Y axis direction) of the resistor as seen from the high resistance unit. The resistor being provided with an extension region results in advantages such as reduced cause for error in the manufacturing process for the resistor. The extension region should be provided as necessary.

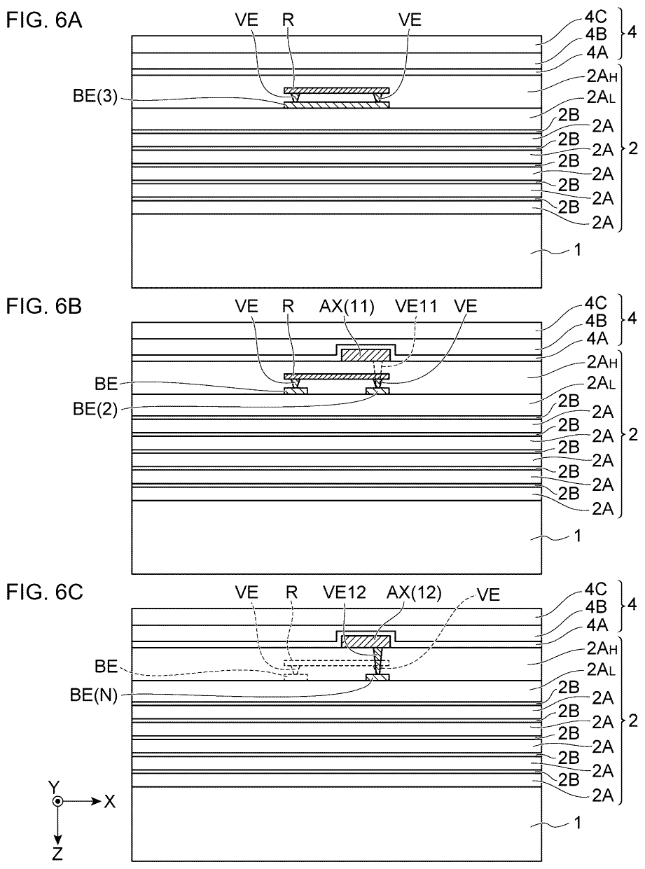

FIG. 6A is a vertical cross-sectional view of a resistor shown in FIG. 5 along the arrow A-A, FIG. 6B is vertical cross-sectional view of a resistor shown in FIG. 5 along the arrow B-B, and FIG. 6C is a vertical cross-sectional view of a resistor shown in FIG. 5 along the arrow C-C.

As shown in FIGS. 6A to 6C, the resistor chip includes a semiconductor substrate 1, an insulating layer 2 provided on the semiconductor substrate 1, and a protective film 4 provided on the insulating layer 2.

The insulating layer 2 includes a plurality of stacked dielectric layers (first dielectric layer 2A, second dielectric layer 2B). At least one of the plurality of dielectric layers (first dielectric layer 2A) includes a silicon oxide as the material thereof. At least one of the plurality of dielectric layers (second dielectric layer 2B) includes a silicon nitride as the material thereof. In this example, the first dielectric layers 2A and the second dielectric layers 2B are alternately stacked. The silicon oxide of this example is SiO₂, but as necessary the element compositional ratio may be modified, and other elements may be included. The silicon nitride of this example is Si₃N₄, but as necessary the element compositional ratio may be modified, and other elements may be included. The thickness of the insulating layer 2 may be 5 μm to 50 μm, inclusive, for example.

The insulating layer 2 includes a lower dielectric layer 2A_{L} formed on the topmost second dielectric layer 2B, and a higher dielectric layer 2A_{H} formed on the lower dielectric layer 2A_{L}. Exemplary materials constituting the lower dielectric layer 2A_{L} and the higher dielectric layer 2A_{H} are the same as those of the first dielectric layer 2A.

The protective film 4 includes a first protective film 4A, a second protective film 4B, and a third protective film 4C stacked in the stated order on the insulating layer 2. The first protective film 4A can be made of an inorganic insulating material such as a silicon oxide or a silicon nitride, and is made of SiO₂, for example. The second protective film 4B is formed on the first protective film 4A. The second protective film 4B is made of an inorganic insulating material such as a silicon oxide or a silicon nitride, and may be made of the same material as or a different material from the first protective film 4A, but is made of a silicon nitride, for example. The third protective film 4C is made of a resin such as polyimide (insulating material).

The embedded electrodes BE (including BE(1) to BE(3), BE(N)) are formed on the lower dielectric layer 2A_{L} and positioned in the higher dielectric layer 2A_{H}. The higher dielectric layer 2A_{H} can include a plurality of dielectric layers (insulating layers), a resistor R (resistor layer) is formed on a specific dielectric layer of the higher dielectric layer 2A_{H}, and the embedded electrode BE and the resistor R are connected by the via electrode VE.

As shown in FIG. 6B, the bottom surface of the first end of the first supplemental electrode AX(11) in the lengthwise direction is connected to the lower embedded electrode BE(2) via the first via electrode VE11 passing through the higher dielectric layer 2A_{H}.

As shown in FIG. 6C, the bottom surface of the lengthwise direction end of the second supplemental electrode AX(12) is connected to the lower embedded electrode BE(N) via the second via electrode VE12 passing through the higher dielectric layer 2A_{H}. The first supplemental electrode AX(11) and the second supplemental electrode AX(12) are disposed adjacent to each other in the Y axis direction, and thus, a capacitor is formed therebetween. A high potential is inputted to the resistor R(first resistor layer) from the embedded electrode BE(2) on the high voltage input side via the via electrode VE. The potential and charge of the embedded electrode BE(2) are transmitted via the first via electrode VE11 to the first supplemental electrode AX(11), and are then transmitted to the second supplemental electrode AX(12) that is capacitance-coupled thereto. The charge flowing through the capacitor flows to the embedded electrode BE(N) positioned directly below the second supplemental electrode AX(12), and is then transmitted to the resistor R(second resistor layer) connected to the embedded electrode BE(N) via the via electrode VE.

As described above, the above-mentioned resistor chip includes the insulating layer 2 formed on the semiconductor substrate 1, and a resistor embedded in the insulating layer 2. The resistor (first high resistance unit RP, second high resistance unit RN) includes the first resistor layer (resistor R(1)), and the first embedded electrode (BE(2)) electrically connected to the first end of the first resistor layer (resistor R(1)). The resistor includes the second resistor layer (resistor R(2)) disposed adjacent to the first resistor layer (resistor R(1)) and electrically connected to the second end of the first resistor layer (resistor R(1)), and the second embedded electrode (BE(N)) electrically connected to the first end of the second resistor layer (resistor R(2)). The resistor includes the first supplemental electrode AX(11). The first supplemental electrode AX(11) extends along the lengthwise direction (X axis direction) of the first resistor layer (resistor R(1)) in a plan view, is electrically connected to the first embedded electrode (BE(2)), and has a greater thickness than the first resistor layer (resistor R(1)). The resistor includes the second supplemental electrode AX(12). The second supplemental electrode AX(12) extends along the lengthwise direction (X axis direction), is electrically connected to the second embedded electrode (BE(N)), has a greater thickness than the second resistor layer (resistor R(2)), is adjacent to the first supplemental electrode AX(11), and forms the first capacitor C11 together with the first supplemental electrode AX(11).

The semiconductor device of this disclosure can rapidly transmit the potential of the first resistor layer (resistor R(1)) to the second resistor layer (resistor R(2)) via the first capacitor C11, and thus, it is unlikely for the potential difference between the first resistor layer (resistor R(1)) and the second resistor layer (resistor R(2)) to become large, thereby improving the breakdown voltage.

Also, in the semiconductor device of this disclosure, where the direction from the edge towards the center in the lengthwise direction (X axis direction) of the first resistor layer (resistor R(1)) is designated as the first direction, the first supplemental electrode AX(11) extends along the first direction from a position directly above the first embedded electrode BE(2) (connection position) in a plan view. The second supplemental electrode AX(12) extends in the first direction from the position directly above the second embedded electrode BE(N) (connection position).

In this structure, the potential of the first resistor layer (resistor R(1)) can be rapidly and reliably transmitted to the second resistor layer (resistor R(2)). The first and second supplemental electrodes may be positioned deeper than the resistor layer, at the position of the embedded electrode layer, or deeper than the embedded electrode.

Next, an example in which three or more supplemental electrodes are electrically connected to the first ends of respective resistors R will be described.

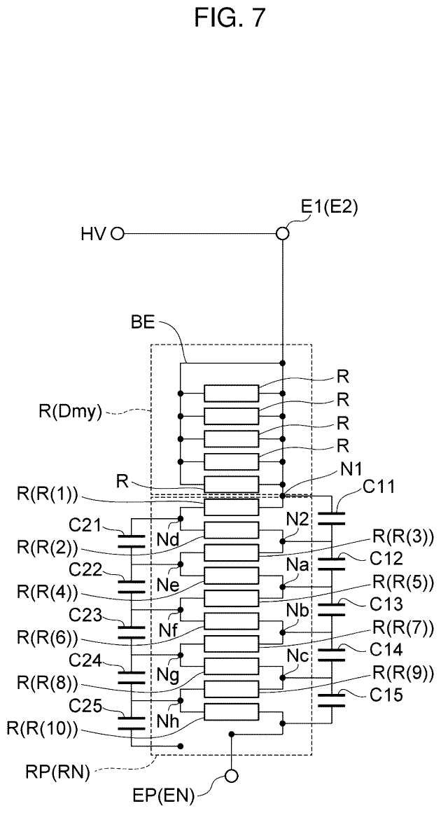

FIG. 7 is a circuit diagram of resistors including the high resistance unit.

The high voltage (HV) input terminal is connected to the first electrode E1 (or second electrode E2). The first electrode E1 is electrically connected to the first high resistance unit RP. The second electrode E2 is electrically connected to the second high resistance unit RN. The first high resistance unit RP (or second high resistance unit RN) includes a plurality of resistors R connected in series. A node in the first high resistance unit RP (or second high resistance unit RN) where a high voltage (high potential) is first inputted is designated as a first node N1. In the first high resistance unit RP (or second high resistance unit RN), a second node N2 of a resistor R adjacent to the resistor R connected to the first node N1 is adjacent to the first node N1.

An end of the first high resistance unit RP (or second high resistance unit RN) is electrically connected to the dummy resistor R(Dmy). The dummy resistor R(Dmy) includes one or more resistors R. Each of the resistors R is a resistor layer, and a specific example of a plan view shape is a linear shape that extends in a line. In the dummy resistor R(Dmy) of this example, both ends of each resistor R are short-circuited, and the plurality of resistors R are connected in parallel. In this example, an embedded electrode BE (embedded wiring line) closest to the high voltage input side short-circuits both ends of the resistors R in the dummy resistor R(Dmy), but the short-circuiting may be performed by another wiring line. The embedded electrode BE for short-circuiting can be disposed directly below the dummy resistor R(Dmy).

If a greater voltage than ground potential is inputted to the first electrode E1 (or second electrode E2), the voltage is transmitted to the first node N1. In a normal state, the potential of the first node N1 undergoes a voltage drop via the one or more resistors R connected in series, and the potential after the voltage drop appears in the second node N2. If the potential of the first node N1 instantaneously increases, the potential of the second node N2 cannot immediately follow this change, and thus, as described in the example above, there are cases in which a large potential difference occurs between the first node N1 and the second node N2, causing damage.

The first capacitor C11 is connected by a pair of supplemental electrodes between the first node N1 and the second node N2. Thus, the potential of the first node N1 is transmitted to the second node N2 via the first capacitor C11.

If the potential of the first node N1 rapidly increases, the potential of the second node N2 increases via the first capacitor C11. Thus, by reducing the potential difference between the first node N1 and the second node N2, damage in the vicinity of a node where a rapid change in voltage occurs can be mitigated.

If the potential of the second node N2 were to rapidly increase, a potential difference would tend to occur at the node between the second node N2 and an adjacent resistor R.

As a countermeasure, this device includes a second capacitor C12. A third supplemental electrode is electrically connected to a third node Na adjacent to the second node N2 to which the second supplemental electrode is connected. The second capacitor C12 is formed between the second supplemental electrode connected to the second node N2 and the third supplemental electrode connected to the third node Na. Thus, the potential difference between the second node N2 and the third node Na is reduced, thereby mitigating damage in the vicinity of the nodes.

Similarly, this device includes a third capacitor C13. A fourth supplemental electrode is electrically connected to a fourth node Nb adjacent to the third node Na to which the third supplemental electrode is connected. The third capacitor C13 is formed between the third supplemental electrode connected to the third node Na and the fourth supplemental electrode connected to the fourth node Nb. Thus, the potential difference between the third node Na and the fourth node Nb is reduced, thereby mitigating damage in the vicinity of the nodes.

Similarly, this device includes a fourth capacitor C14. A fifth supplemental electrode is electrically connected to a fifth node Nc adjacent to the fourth node Nb to which the fourth supplemental electrode is connected. The fourth capacitor C14 is formed between the fourth supplemental electrode connected to the fourth node Nb and the fifth supplemental electrode connected to the fifth node Nc. Thus, the potential difference between the fourth node Nb and the fifth node Nc is reduced, thereby mitigating damage in the vicinity of the nodes. By a similar configuration, this device can include the fifth capacitor C15, or even more capacitors.

A node Nd is present on the opposite side to the first node N1 of the first resistor layer (resistor R(1)) in the high resistance unit, the node Nd is connected to a supplemental electrode, and this supplemental electrode together with a supplemental electrode opposite thereto and capacitance-coupled thereto together form a first capacitor (C21) on the opposite side. The other supplemental electrode of the opposite side first capacitor (C21) is connected to a node Ne. The connective relationship between the opposite side first to fifth capacitors (C21-C25) is similar to that of the first to fifth capacitors (C11-C15). The opposite side first capacitor (C21) is connected between the node Nd and the node Ne, the opposite side second capacitor (C22) is connected between the node Ne and a node Nf, the opposite side third capacitor (C23) is connected between the node Nf and a node Ng, the opposite side fourth capacitor (C24) is connected between the node Ng and a node Nh, and the opposite side fifth capacitor (C24) is connected between the node Nh and a given potential.

The number of capacitors constituted of the supplemental electrodes here is merely an example, and the number of supplemental electrodes connected to first ends of the resistors R can be set to four or more, six or more, eight or more, or ten or more, for example.

The range for the capacitance of an exemplary first capacitor (C11) (or combined capacitance depending on the structure) can be set to a similar range to the first capacitor C11 in the examples of FIGS. 4 to 6C. The range for the capacitances of exemplary capacitors (C11-C15, C21-C25) (or combined capacitances depending on the structure) can also be set to a similar range to the first capacitor C11 in the above examples. Other ranges may be set.

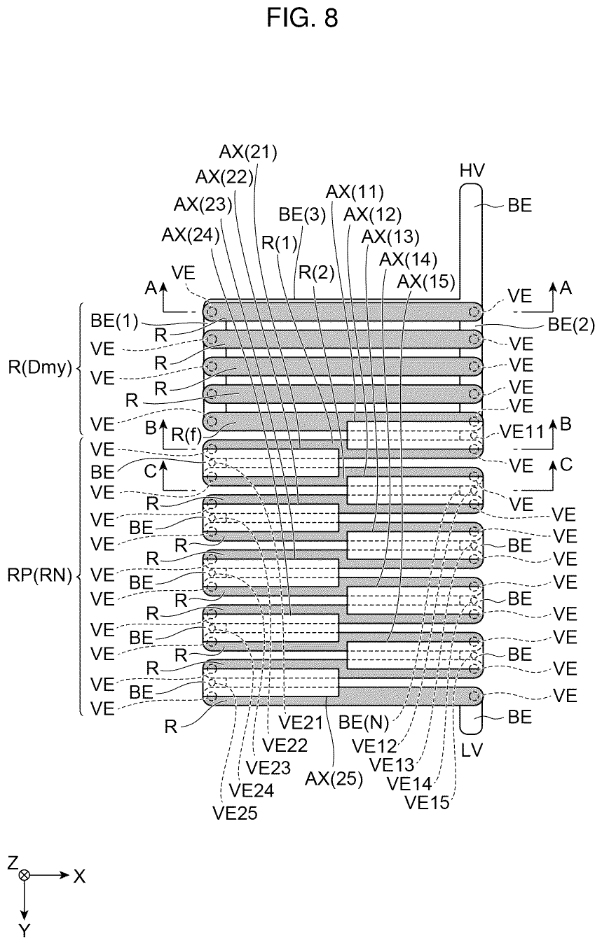

FIG. 8 is a plan view of the resistors including the high resistance unit shown in FIG. 7. The resistors, the embedded electrodes, and the dummy wiring lines are, in reality, embedded in an insulating layer, but for ease of explanation, the insulating layer is not shown.

Each of the resistors R extends in the X axis direction, and the plurality of resistors R are arrayed in the Y axis direction. A via electrode VE is physically and electrically connected to the bottom surface of both ends of each of the resistors R, and the via electrode VE is physically and electrically connected to the embedded electrode BE.

In the dummy resistor R(Dmy), the embedded electrode BE includes a first connection region BE(1) to which all first ends of the plurality of resistors R are connected, a second connection region BE(2) to which all second ends are connected, and a third connection region BE(3) that connects the foregoing connection regions.

In the first high resistance unit RP (or second high resistance unit RN), the embedded electrodes BE connect the first ends of the nth and (n+1)th resistors R in the Y axis direction, and connect the second ends of the (n+1)th and (n+2)th resistors R(n being a natural number, and typically an odd number).

In one possible structure, the vertical positional relationship between the resistors R and the via electrodes VE and embedded electrodes BE is reversed. In such a case, the resistors R are positioned in a lower layer than the via electrodes VE and the embedded electrodes BE.

The embedded electrode BE connected to the electrode to which a high voltage (HV) is applied is connected via the via electrode VE to a first end on the input side of a first resistor layer (resistor R(1)) of the high resistance unit via the embedded electrode BE (second connection region BE(2)) positioned below the first end of the dummy resistor R(Dmy).

The first end of the last resistor R(f) (last dummy resistor layer) of the dummy resistor R(Dmy) is also connected to the embedded electrode BE (second connection region BE(2)) via the via electrode VE. That is, the first end of the last resistor R(f) of the dummy resistor R(Dmy) and the first end of the first resistor layer (resistor R(1)) are both connected to the second connection region BE(2) constituting the embedded electrode. A first supplemental electrode AX(11) is disposed above the region between the last resistor R(f) and the first resistor layer (resistor R(1)). The first supplemental electrode AX(11) is electrically connected to the second connection region BE(2) via a first via electrode VE11.

The first end of a second second resistor layer (resistor R(2)) subsequent to the first second resistor layer is connected via the via electrode VE to the embedded electrode BE(N). An embedded electrode BE(N) connects the first end of the adjacent resistor R via the via electrode VE, similar to other embedded electrodes BE. The embedded electrode BE(N) is connected via a second via electrode VE12 to a second supplemental electrode AX(12) positioned thereabove.

The first supplemental electrode AX(11) extends in the X axis direction. The second supplemental electrode AX(12) extends in the X axis direction. The first supplemental electrode AX(11) and the second supplemental electrode AX(12) are adjacent to each other in the Y axis direction and a gap is present therebetween. In this gap, a dielectric constituting a protective film or an insulating layer is placed. Thus, the first supplemental electrode AX(11) and the second supplemental electrode AX(12) constitute a capacitor. The thickness of the first supplemental electrode AX(11) is greater than the thickness of the first resistor layer (resistor R(1)). The thickness of the first supplemental electrode AX(12) is greater than the thickness of the second resistor layer (resistor R(2)). The thickness of each of all of the supplemental electrodes is greater than the thickness of each resistor layer. This is due to the fact that if the supplemental electrode is too thin, a capacitance sufficient to transmit current cannot be attained.

The plurality of resistors R in the high resistance unit are connected in series between the input-side electrode applying the high voltage (HV) and the output electrode on the low voltage (LV) side.

The second supplemental electrode AX(12) extends in the X axis direction. The third supplemental electrode AX(13) extends in the X axis direction. The second supplemental electrode AX(12) and the third supplemental electrode AX(13) are adjacent to each other in the Y axis direction and a gap is present therebetween. In this gap, a dielectric constituting a protective film or an insulating layer is placed. Thus, the second supplemental electrode AX(12) and the third supplemental electrode AX(13) constitute a capacitor.

Similarly, the third supplemental electrode AX(13) extends in the X axis direction. The fourth supplemental electrode AX(14) extends in the X axis direction. The third supplemental electrode AX(13) and the fourth supplemental electrode AX(14) are adjacent to each other in the Y axis direction and a gap is present therebetween. In this gap, a dielectric constituting a protective film or an insulating layer is placed. Thus, the third supplemental electrode AX(13) and the fourth supplemental electrode AX(14) constitute a capacitor.

Similarly, the fourth supplemental electrode AX(14) extends in the X axis direction. The fifth supplemental electrode AX(15) extends in the X axis direction. The fourth supplemental electrode AX(14) and the fifth supplemental electrode AX(15) are adjacent to each other in the Y axis direction and a gap is present therebetween. In this gap, a dielectric constituting a protective film or an insulating layer is placed. Thus, the fourth supplemental electrode AX(14) and the fifth supplemental electrode AX(15) constitute a capacitor.

The first supplemental electrode AX(11) is connected to the embedded electrode directly therebelow via the first via electrode VE11. The second supplemental electrode AX(12) is connected to the embedded electrode BE directly therebelow via the second via electrode VE12. The third supplemental electrode AX(13) is connected to the embedded electrode BE directly therebelow via a third via electrode VE13. The fourth supplemental electrode AX(14) is connected to the embedded electrode BE directly therebelow via a fourth via electrode VE14. The fifth supplemental electrode AX(15) is connected to the embedded electrode BE directly therebelow via a fifth via electrode VE15.

Similarly, a first supplemental electrode AX(21), a second supplemental electrode AX(22), a third supplemental electrode AX(23), a fourth supplemental electrode AX(24), and a fifth supplemental electrode AX(25) positioned on the opposite edge of each resistor layer are connected to the embedded electrode BE directly therebelow via a first via electrode VE21, a second via electrode VE22, a third via electrode VE23, a fourth via electrode VE24, and a fifth via electrode VE25, respectively. Each embedded electrode is connected to the first end of the nth resistor layer and the first end of the (n+1)th resistor layer (n being a natural number, and typically an odd number).

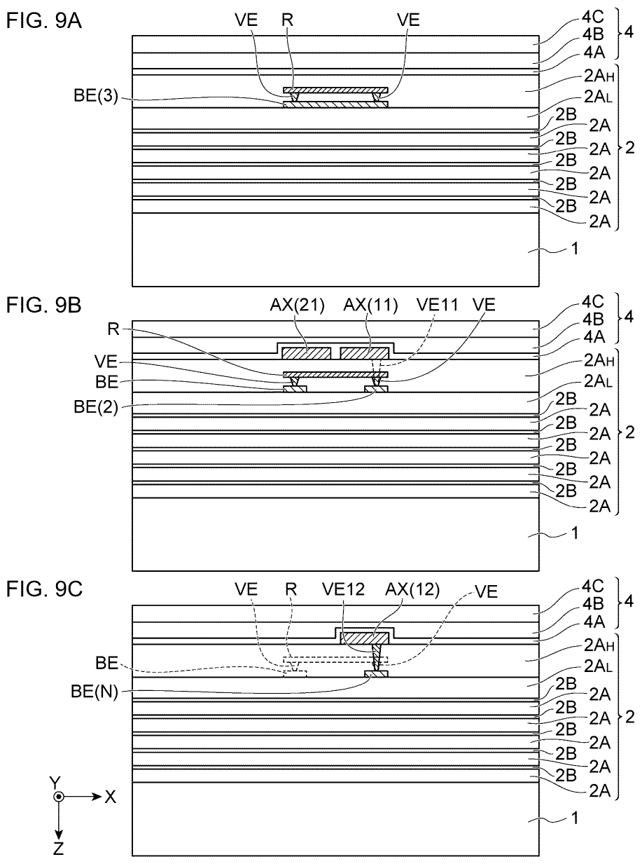

FIG. 9A is a vertical cross-sectional view of a resistor shown in FIG. 8 along the arrow A-A, FIG. 9B is vertical cross-sectional view of a resistor shown in FIG. 8 along the arrow B-B, and FIG. 9C is a vertical cross-sectional view of a resistor shown in FIG. 8 along the arrow C-C.

As shown in FIGS. 9A to 9C, the resistor chip includes the semiconductor substrate 1, the insulating layer 2 provided on the semiconductor substrate 1, and the protective film 4 provided on the insulating layer 2.

The structures of the insulating layer 2 and the protective film 4 are the same as those of FIGS. 6A to 6C.

The embedded electrodes BE (including BE(1) to BE(3), BE(N)) are formed on the lower dielectric layer 2A_{L} and positioned in the higher dielectric layer 2A_{H}. The higher dielectric layer 2A_{H} can include a plurality of dielectric layers (insulating layers), a resistor R (resistor layer) is formed on a specific dielectric layer of the higher dielectric layer 2A_{H}, and the embedded electrode BE and the resistor R are connected by the via electrode VE. Also, as shown in FIG. 9B, the bottom surface of the first supplemental electrode AX(11) is connected to the lower embedded electrode BE(2) via the first via electrode VE11 passing through the higher dielectric layer 2A_{H}. As shown in FIG. 9C, the bottom surface of the second supplemental electrode AX(12) is connected to the lower embedded electrode BE(N) via the second via electrode VE12 passing through the higher dielectric layer 2A_{H}. The respective supplemental electrodes are adjacent to each other in the Y axis direction and a protective film is present therebetween. The capacitance between the supplemental electrodes can also be changed by changing the permittivity of the protective film. The capacitances of the capacitors formed by the supplemental electrodes are dependent on the sizes of the gaps, the facing areas between the supplemental electrodes, and the permittivities of the dielectrics therebetween. The range in the sizes of the gaps between the supplemental electrodes can be set so as to satisfy exemplary capacitances of the capacitors.

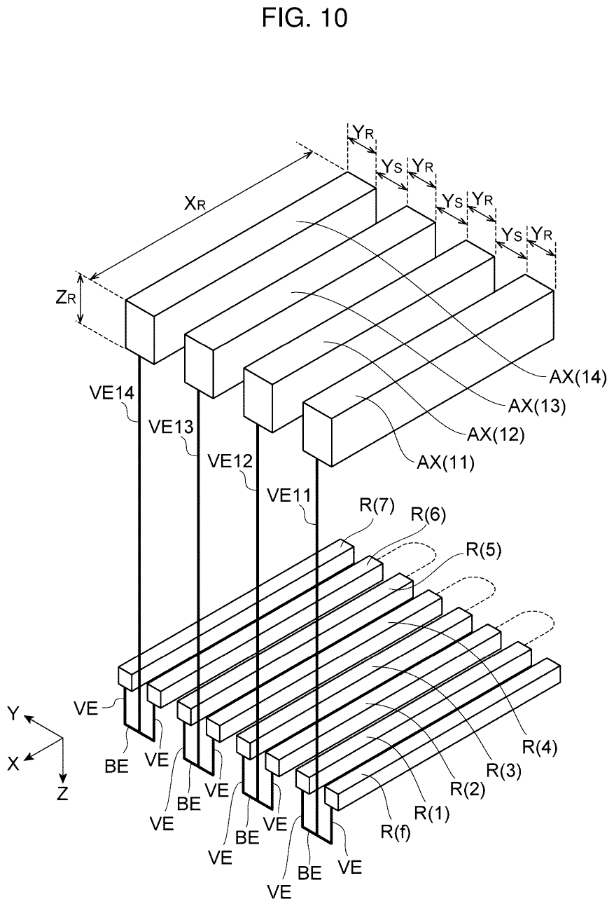

FIG. 10 is a perspective view of an edge structure including supplemental electrodes and a resistor layer.

A length X_{R} along the lengthwise direction (X axis direction) of the first supplemental electrode AX(11) is 100 μm to 300 μm, inclusive, and the length X_{R} along the lengthwise direction (X axis direction) of the second supplemental electrode AX(12) is 100 μm to 300 μm, inclusive. Similarly, the length X_{R} along the X axis direction of the Nth supplemental electrode AX is 100 μm to 300 μm, inclusive (N=1, 2, 3 . . . ). A dimension Z_{R} along the Z axis direction (thickness) of the Nth supplemental electrode AX is 1 μm to 3 μm, inclusive. A dimension Y_{R} along the Y axis direction of the Nth supplemental electrode AX does not affect the capacitance of the capacitor, and thus, may be set according to the width of the adjacent resistor layer. The gap Y_{S} along the Y axis direction between the Nth supplemental electrode AX and the (N+1)th supplemental electrode AX is 1 μm to 3 μm. The dielectric positioned between the supplemental electrodes can be made of a silicon oxide, a silicon nitride, or the like, but is not limited to these materials. The capacitance of the capacitor that can be set according to the conditions is 1 fF or greater. It is more preferable, from the perspective of rapid transmission of potential and charge, that the capacitance of the capacitor be 10 fF or greater.

The connective relationships of this example will be described in detail. The dummy resistor layer (last dummy resistor layer R(f)) is disposed adjacent to the first resistor layer (first resistor R(1)) on the side opposite to the second resistor layer (second resistor R(2)), and the first end of the dummy resistor layer is electrically connected to the first embedded electrode BE. A third resistor layer (third resistor R(3)) is disposed adjacent to the second resistor layer (second resistor R(2)) on the side opposite to the first resistor layer (first resistor R(1)), and the first end of the third resistor layer is electrically connected to the second embedded electrode BE. The high potential applied to the last dummy resistor layer R(f) is transmitted to the embedded electrode BE positioned below the second via electrode VE12 via the capacitor formed by the first via electrode VE11, the first supplemental electrode AX(11), and the second supplemental electrode AX(12), and this potential is transmitted via the via electrode VE to the second resistor layer (second resistor R(2)) and the third resistor layer (third resistor R(3)) connected thereto. Similarly, the third via electrode VE13 connects the third supplemental electrode AX(13) to the embedded wiring line BE. The fourth via electrode VE14 connects the fourth via electrode AX(14) to the embedded wiring line BE.

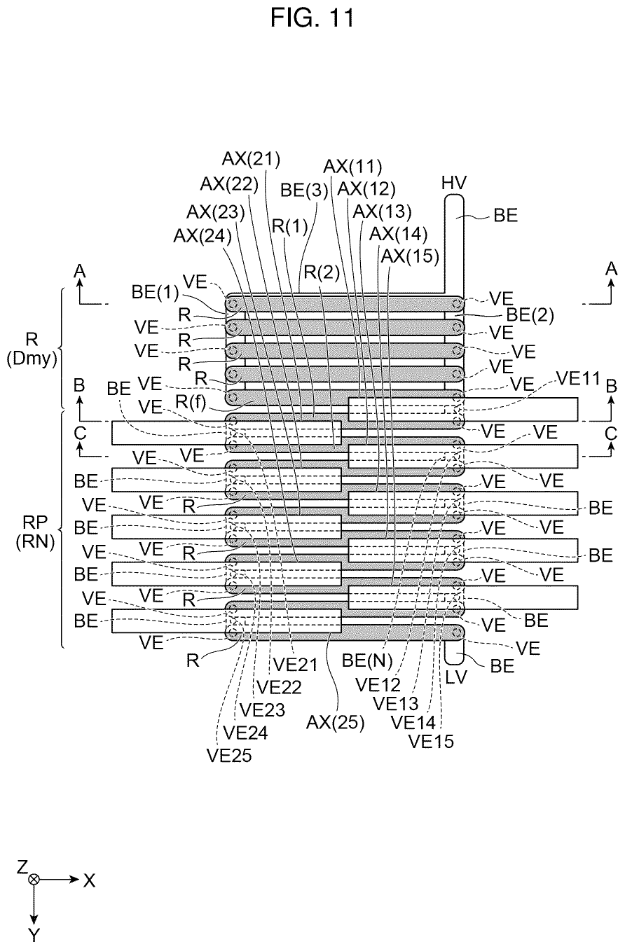

FIG. 11 is a plan view of the resistors including the high resistance unit.

The resistors of this example have supplemental electrodes with a greater X axis direction dimension and protrude outward in the X axis direction of the resistors, as compared to the resistors shown in FIG. 8. In other words, all of the supplemental electrodes (AX(11)-AX(15), AX(21)-AX(25)) include a region that protrudes outside of the first high resistance unit RP (or second high resistance unit RN) so as not to overlap the resistors R(resistor layers) in a plan view. The structure of the resistors of this example is otherwise the same as that of the resistors shown in FIG. 8.

In other words, in the semiconductor chip of this disclosure, in a plan view, the first supplemental electrode AX(11) also extends in the direction opposite to the first direction (direction from the edge to the center of each resistor R(resistor layer)) from the position directly above the first embedded electrode (BE), and the second supplemental electrode AX(12) also extends in the direction opposite to the first direction from the position directly above the second embedded electrode (BE). In this structure, the capacitance of the capacitor formed by the supplemental electrodes can be increased.

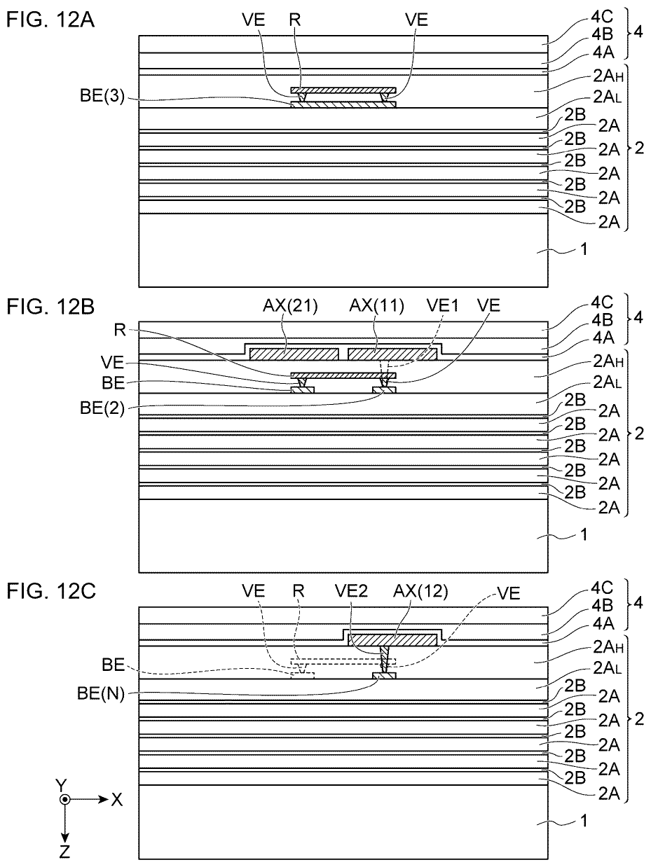

FIG. 12A is a vertical cross-sectional view of a resistor shown in FIG. 11 along the arrow A-A, FIG. 12B is vertical cross-sectional view of a resistor shown in FIG. 11 along the arrow B-B, and FIG. 12C is a vertical cross-sectional view of a resistor shown in FIG. 11 along the arrow C-C.

As shown in FIGS. 12A to 12C, the resistor chip includes the semiconductor substrate 1, the insulating layer 2 provided on the semiconductor substrate 1, and the protective film 4 provided on the insulating layer 2.

The structures of the insulating layer 2 and the protective film 4 are the same as those of FIGS. 9A to 9C, with the only difference being the X axis direction dimensions of the supplemental electrodes.

In the structure of this example, as shown in FIG. 12B, the bottom surface of the first supplemental electrode AX(11) is connected to the lower embedded electrode BE(2) via the first via electrode VE11 passing through the higher dielectric layer 2_{AH}. The first supplemental electrode AX(11) extends not only in the negative direction of the X axis but also the positive direction (the direction opposite to the first direction towards the center) from the position where the first via electrode VE11 is present.

The bottom surface of the first supplemental electrode AX(21) on the opposite side is connected to the lower embedded electrode BE via the via electrode passing through the higher dielectric layer 2A_{H}. The first supplemental electrode AX(21) on the opposite side extends not only in the positive direction of the X axis but also the negative direction (the direction opposite to the first direction towards the center) from the position where the via electrode is present.

As shown in FIG. 12C, the bottom surface of the second supplemental electrode AX(12) is connected to the lower embedded electrode BE(N) via the second via electrode VE12 passing through the higher dielectric layer 2A_{H}. The second supplemental electrode AX(12) extends not only in the negative direction of the X axis but also the positive direction (the direction opposite to the first direction towards the center).

The respective supplemental electrodes are adjacent to each other in the Y axis direction and a protective film is present therebetween. The capacitance between the supplemental electrodes can also be changed by changing the permittivity of the protective film.

The capacitances of the capacitors formed by the supplemental electrodes are dependent on the sizes of the gaps, the facing areas between the supplemental electrodes, and the permittivities of the dielectrics therebetween. The range in the sizes of the gaps between the supplemental electrodes can be set so as to satisfy exemplary capacitances of the capacitors.

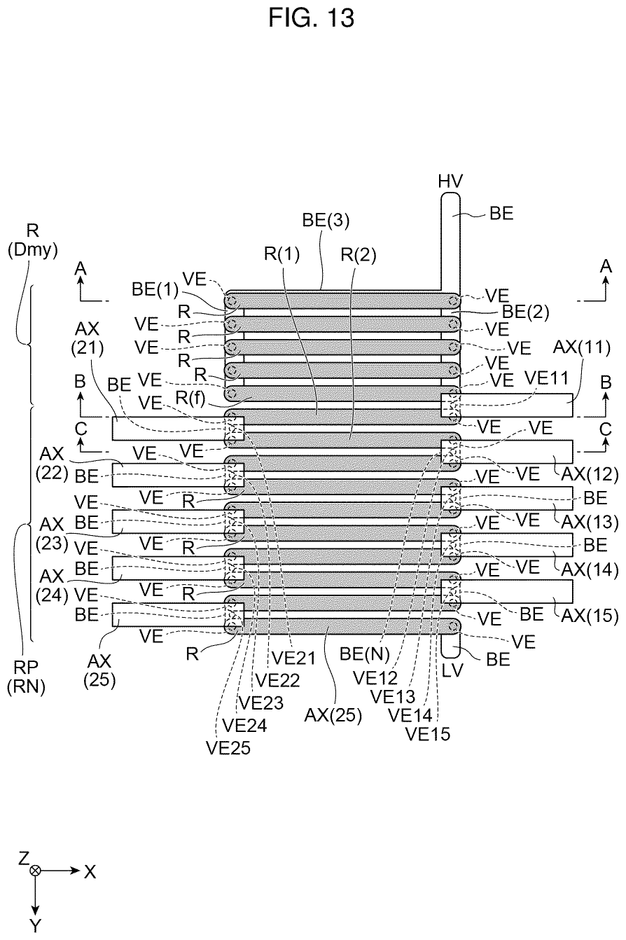

FIG. 13 is a plan view of the resistors including the high resistance unit.

The resistors of this example have supplemental electrodes with a smaller X axis direction dimension and protrude outward only in the X axis direction of the resistors, as compared to the resistors shown in FIG. 11. In other words, all of the supplemental electrodes (AX(11)-AX (15), AX(21)-AX(25)) include a region that protrudes outside of the first high resistance unit RP (or second high resistance unit RN) so as not to overlap each of the resistors R (resistor layers) in a plan view, but essentially, the supplemental electrodes do not protrude into the region to the inside of the high resistance unit. As a matter of course, in the region where the via electrode is provided to the supplemental electrode (dimension that is multiple factors or less the Y axis direction width of each resistor R(resistor layer)), the supplemental electrode slightly overlaps the resistor R. The structure of the resistors of this example is otherwise the same as that of the resistors shown in FIG. 11.

In other words, in the semiconductor chip of this disclosure, in a plan view, the first supplemental electrode AX(11) extends in the direction opposite to the first direction (direction from the edge to the center of each resistor R(resistor layer)) from the position directly above the first embedded electrode BE(2). The second supplemental electrode AX(12) extends in the direction opposite to the first direction from the position directly above the second embedded electrode BE(N). In this structure, the capacitor formed by the supplemental electrodes can be freely designed without being limited by the design of the resistor region.

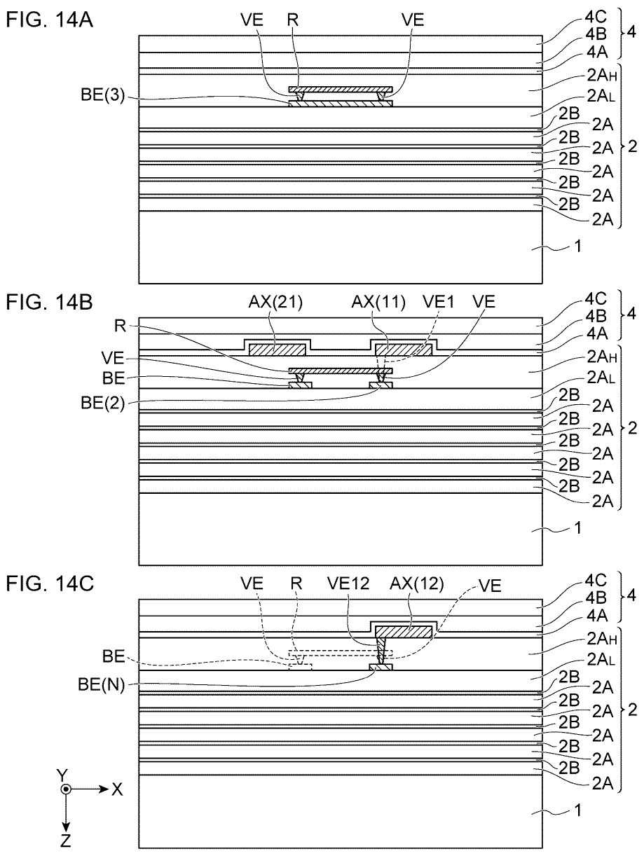

FIG. 14A is a vertical cross-sectional view of a resistor shown in FIG. 13 along the arrow A-A, FIG. 14B is vertical cross-sectional view of a resistor shown in FIG. 13 along the arrow B-B, and FIG. 14C is a vertical cross-sectional view of a resistor shown in FIG. 13 along the arrow C-C.

The structures of the insulating layer 2 and the protective film 4 are the same as those of FIGS. 12A to 12C, with the only difference being the X axis direction dimensions of the supplemental electrodes.

In the structure of this example, as shown in FIG. 14B, the bottom surface of the first supplemental electrode AX(11) is connected to the lower embedded electrode BE(2) via the first via electrode VE11 passing through the higher dielectric layer 2A_{H}. The first supplemental electrode AX(11) extends only in the positive direction (the direction opposite to the first direction towards the center) of the X axis from the position where the first via electrode VE11 is present.

The bottom surface of the first supplemental electrode AX(21) on the opposite side is connected to the lower embedded electrode BE via the via electrode passing through the higher dielectric layer 2A_{H}. The first supplemental electrode AX(21) on the opposite side extends only in the negative direction (the direction opposite to the first direction towards the center) of the X axis from the position where the via electrode is present.

As shown in FIG. 12C, the bottom surface of the second supplemental electrode AX(12) is connected to the lower embedded electrode BE(N) via the second via electrode VE12 passing through the higher dielectric layer 2A_{H}. The second supplemental electrode AX(12) extends only in the positive direction of the X axis (the direction opposite to the first direction towards the center).

The respective supplemental electrodes are adjacent to each other in the Y axis direction and a protective film is present therebetween. The capacitance between the supplemental electrodes can also be changed by changing the permittivity of the protective film. The capacitances of the capacitors formed by the supplemental electrodes are dependent on the sizes of the gaps, the facing areas between the supplemental electrodes, and the permittivities of the dielectrics therebetween. The range in the sizes of the gaps between the supplemental electrodes can be set so as to satisfy exemplary capacitances of the capacitors.

The above-mentioned supplemental electrodes are disposed above each resistor R (resistor layer) but alternatively may be formed at a position deeper than the resistors R by modifying the embedded electrodes, for example.

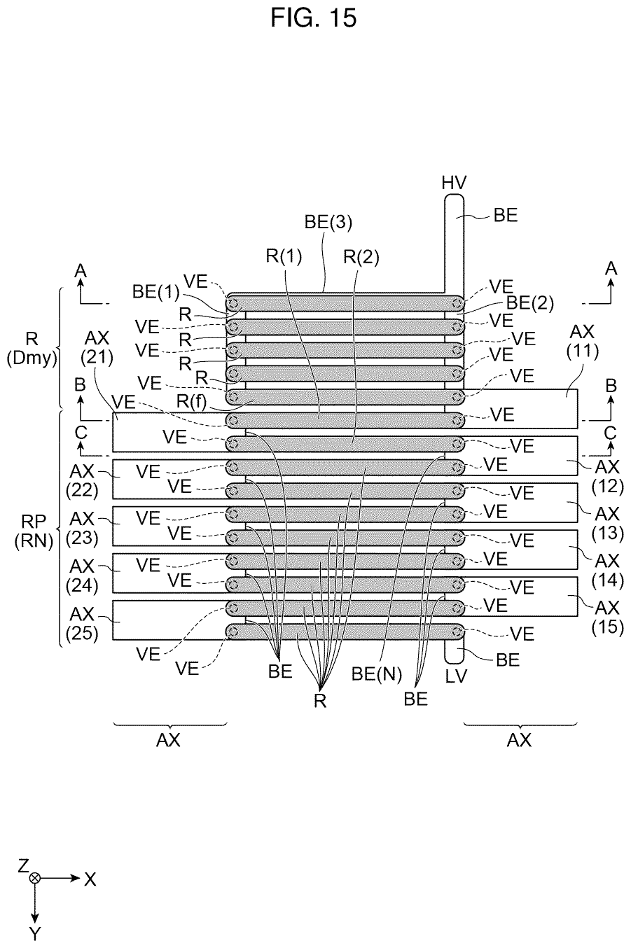

FIG. 15 is a plan view of the resistors including the high resistance unit.

As compared to the resistors shown in FIG. 13, the resistors of this example have embedded electrodes BE, the shape of which is modified to that similar to the supplemental electrodes, instead of being provided with supplemental electrodes formed above the resistor layer. In the example shown in FIG. 15, the Y axis direction width of the supplemental electrodes AX is set slightly wider than for those of FIG. 13, but the configuration is not limited thereto.

In this structure, the supplemental electrodes and the via electrodes for connecting the supplemental electrodes to the embedded electrodes shown in FIG. 13 are eliminated, and instead, each embedded electrode BE extends along the X axis direction. In other words, the region of the extended portion of the embedded electrode BE is the supplemental electrode AX. The supplemental electrodes (AX(11)-AX (15), AX(21)-AX(25)) that are extension regions of the embedded electrodes BE are regions that protrude outside of the first high resistance unit RP (or second high resistance unit RN) in a plan view. Between supplemental electrodes adjacent to each other in the Y axis direction, a capacitor is formed in a manner similar to the structure shown in FIG. 13.

In the resistor chip of this disclosure, the first supplemental electrode AX(11) is continuous with the first embedded electrode BE(2), and is a first extension section of the first embedded electrode BE(2) that extends in the direction opposite to the first direction (direction from the edge to the center of resistor R(resistor layer)). The second supplemental electrode AX(12) is continuous with the second embedded electrode BE(N), and is a second extension section of the second embedded electrode BE(N) that extends in the direction opposite to the first direction. Similarly, each supplemental electrode is continuous with the corresponding embedded electrode BE, and is an extension section of the embedded electrode BE that extends along the direction opposite to the first direction. These supplemental electrodes may alternatively extend in the first direction. According to this structure, the number of elements constituting components is reduced, which improves productivity and also allows for a reduction in the thickness direction dimension.

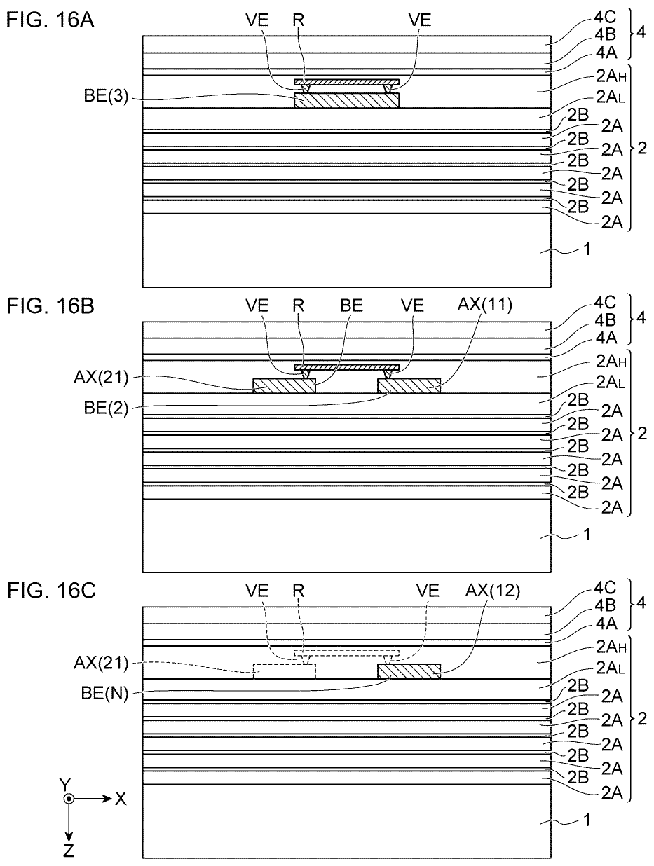

FIG. 16A is a vertical cross-sectional view of a resistor shown in FIG. 15 along the arrow A-A, FIG. 16B is vertical cross-sectional view of a resistor shown in FIG. 15 along the arrow B-B, and FIG. 16C is a vertical cross-sectional view of a resistor shown in FIG. 15 along the arrow C-C.

The structures of the insulating layer 2 and the protective film 4 are the same as those of FIGS. 14A to 14C, with the only difference being that the supplemental electrodes are constituted of the embedded electrodes.

In the structure of this example, as shown in FIG. 16B, the first supplemental electrode AX(11) is formed in the higher dielectric layer 2A_{H}, and is continuous with the embedded electrode BE(2). The embedded electrodes forming the supplemental electrodes in this structure have a greater thickness in order to attain increased capacitance for the capacitors. The first supplemental electrode AX(11) extends in the positive direction (the direction opposite to the first direction towards the center) of the X axis from the position where the via electrode VE connecting the resistor R to the embedded electrode BE(2) is present.

The first supplemental electrode AX(21) continuous with the embedded electrode BE on the opposite side in FIG. 16B is formed in the higher dielectric layer 2A_{H}, and is continuous with the embedded electrode BE. The first supplemental electrode AX(21) extends in the negative direction (the direction opposite to the first direction towards the center) of the X axis from the position where the via electrode VE connecting the resistor R to the embedded electrode BE is present.

As shown in FIG. 16C, the second supplemental electrode AX(12) is formed in the higher dielectric layer 2A_{H}, and is continuous with the embedded electrode BE(N). The second supplemental electrode AX(12) extends in the positive direction of the X axis (the direction opposite to the first direction towards the center).

The respective supplemental electrodes are adjacent to each other in the Y axis direction and the insulating layer 2 is present therebetween. The capacitance between the supplemental electrodes can also be changed by changing the permittivity of the insulating layer 2. The capacitances of the capacitors formed by the supplemental electrodes are dependent on the sizes of the gaps, the facing areas between the supplemental electrodes, and the permittivities of the dielectrics therebetween. The range in the sizes of the gaps between the supplemental electrodes can be set so as to satisfy exemplary capacitances of the capacitors.

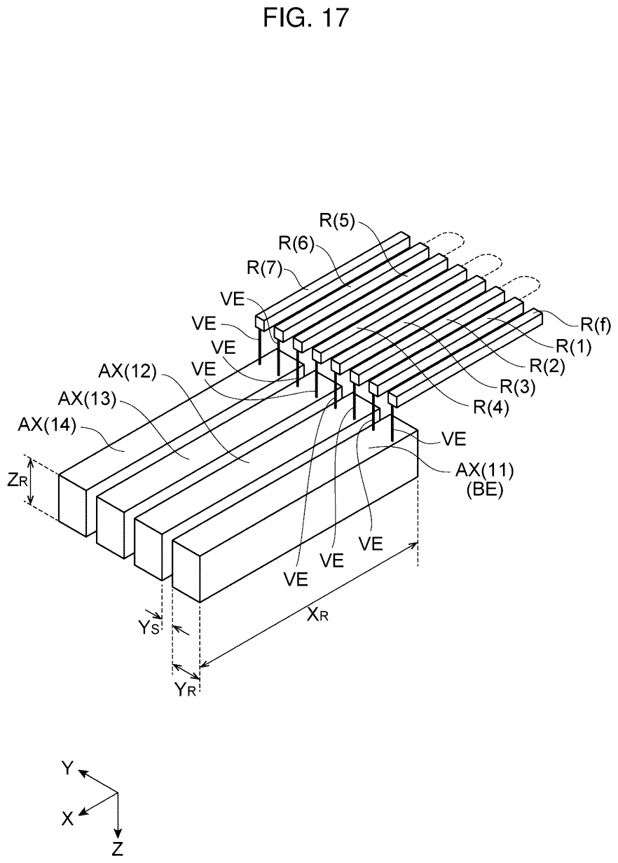

FIG. 17 is a perspective view of an edge structure including supplemental electrodes that double as embedded electrodes, and a resistor layer.

The first supplemental electrode AX(11), which is the extension region of the embedded electrode BE, extends in the X axis direction. The length X_{R} along the X axis direction (lengthwise direction) of the first supplemental electrode AX(11) is 100 μm to 300 μm, inclusive. The length X_{R} along the X axis direction (lengthwise direction) of the second supplemental electrode AX(12) is 100 μm to 300 μm, inclusive. Similarly, the length X_{R} along the X axis direction of the Nth supplemental electrode AX is 100 μm to 300 μm, inclusive (N=1, 2, 3 . . . ). A dimension Z_{R} along the Z axis direction (thickness) of the Nth supplemental electrode AX is 1 μm to 3 μm, inclusive. A dimension Y_{R} along the Y axis direction of the Nth supplemental electrode AX does not affect the capacitance of the capacitor, and thus, may be set according to the width of the adjacent resistor layer. The gap Y_{S} along the Y axis direction between the Nth supplemental electrode AX and the (N+1)th supplemental electrode AX is 1μm to 3 μm. The dielectric positioned between the supplemental electrodes can be made of a silicon oxide, a silicon nitride, or the like, but is not limited to these materials. The capacitance of the capacitor that can be set according to the conditions is 1 fF or greater. It is more preferable, from the perspective of rapid transmission of potential and charge, that the capacitance of the capacitor be 10 fF or greater.

In the above structure, each resistor R(resistor layer) may be divided into a plurality of pieces, with the plurality of partial resistors being electrically connected by embedded electrodes or the like. Also, it is possible to modify the structure of the embedded electrodes connecting the partial resistors, and use the modified embedded electrodes as supplemental electrodes.

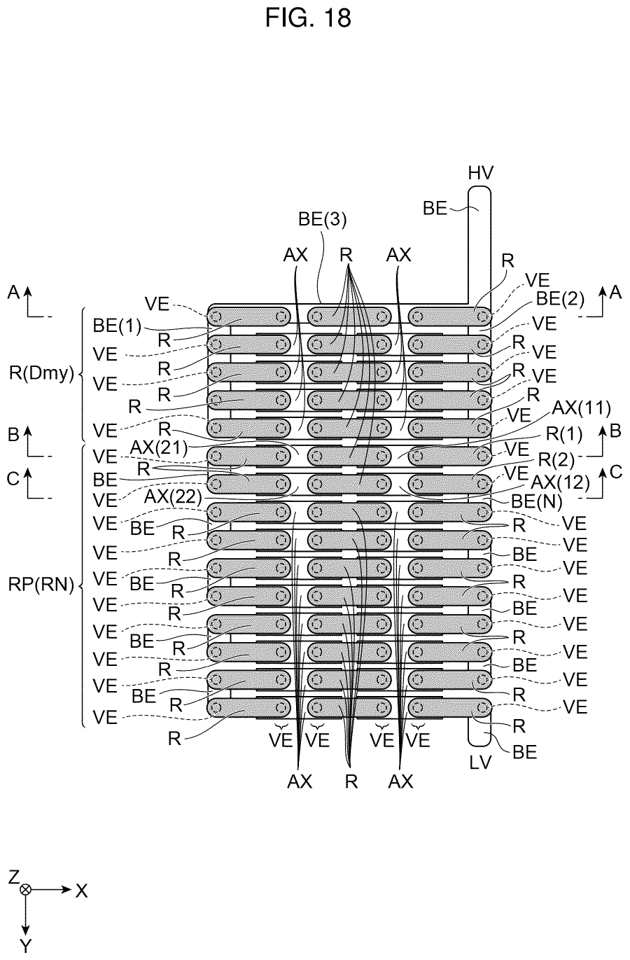

FIG. 18 is a plan view of the resistors including the high resistance unit.

In the resistor (first high resistance unit RP or second high resistance unit RN) of this example, one resistor in each line is divided into a plurality of pieces, and within each row, a plurality of partial resistors are provided.

In other words, the resistor of this example includes a plurality of first partial resistors R disposed as three separated pieces within a first line (a given line along the X axis) in a plan view. In the first line including a first partial resistor R(1), for example, there are a total of three first partial resistors R. In the first line, the first supplemental electrode AX(11) extending along the first line and the first supplemental electrode AX(21) on the opposite adjacent side to the former supplemental electrode in the X axis direction are provided. The first supplemental electrode AX(11) connects the first partial resistor R(1) to the first partial resistor R adjacent thereto in the X axis direction and positioned at the center in the X axis direction. The first supplemental electrode AX(21) on the opposite side connects the first partial resistor R positioned in the center in the X axis direction to the first partial resistor R adjacent thereto in the X axis direction and positioned on the negative direction side thereof in the X axis direction.

Similarly, the resistor of this example includes a plurality of second partial resistors R disposed as three separated pieces within a second line (a line adjacent to the given line along the X axis) adjacent to the first line in a plan view. In the second line including a second partial resistor R(2), for example, there are a total of three second partial resistors R. In the second line, the second supplemental electrode AX(12) extending along the second line and the second supplemental electrode AX(22) on the opposite adjacent side to the former supplemental electrode in the X axis direction are provided. The second supplemental electrode AX(12) connects the second partial resistor R(2) to the second partial resistor R adjacent thereto in the X axis direction and positioned at the center in the X axis direction. The second supplemental electrode AX(22) on the opposite side connects the second partial resistor R positioned in the center in the X axis direction to the second partial resistor R adjacent thereto in the X axis direction and positioned on the negative direction side thereof in the X axis direction.

Thus, the first supplemental electrode AX(11) in the first line and the second supplemental electrode AX(12) in the second line constitute a capacitor. Similarly, the first supplemental electrode AX(21) on the opposite side in the first line and the second supplemental electrode AX(22) on the opposite side in the second line constitute a capacitor. The function of the capacitors is similar to the function of the above-mentioned capacitors, which is to mitigate a rapid increase in the potential difference between resistors adjacent to each other in the Y axis direction. The transmission of the potential and charge by such capacitors is sometimes delayed due to the resistance of the first partial resistor R(1) and the second partial resistor R(2), but essentially exhibits similar performance in mitigating the potential difference.

The length along the lengthwise direction (first line direction: X axis) of the first supplemental electrode AX(11) is 100 μm to 300 μm, inclusive, the length along the lengthwise direction (second line direction: X axis) of the second supplemental electrode AX(12) is 100 μm to 300 μm, inclusive, and the capacitance of the capacitor formed therebetween can be set to 1 fF or greater. It is preferable, from the perspective of rapid transmission of potential and charge, that the capacitance of the capacitor be 10 fF or greater.

Similarly, the length along the lengthwise direction (first line direction: X axis) of the opposite side first supplemental electrode AX(21) is 100 μm to 300 μm, inclusive, the length along the lengthwise direction (second line direction: X axis) of the opposite side second supplemental electrode AX(22) is 100 μm to 300 μm, inclusive, and the capacitance of the capacitor formed therebetween can be set to 1 fF or greater. It is preferable, from the perspective of rapid transmission of potential and charge, that the capacitance of the capacitor be 10 fF or greater. The shape of the supplemental electrodes functioning as embedded electrodes for connection can have similar values to those of FIG. 17.

The combined capacitance of a group of capacitors constituted of all supplemental electrodes in the first line and the second line may be set to satisfy the above-mentioned range.

The plurality of first partial resistors R in the first line are electrically connected to the plurality of second partial resistors R in the second line via the embedded electrodes BE and the via electrodes VE positioned on the negative direction side of the X axis. The plurality of partial resistors R in the second line are electrically connected to a plurality of partial resistors R in a third line via the embedded electrodes BE and the via electrodes VE positioned on the positive direction side of the X axis. The relationship between the embedded electrode BE and the via electrode VE is as described above, and the via electrode VE is connected to the bottom surface of each resistor R(resistor layer) and the top surface of the embedded electrode BE. The connective structure having such a relationship is repeated for fourth and further lines.

The thickness of each of supplemental electrodes (thickness in the Z axis direction) is greater than the thickness of each partial resistor. That is, the thickness of the first supplemental electrode AX(11) is greater than the thickness of the first partial resistor R(1). The thickness of the second supplemental electrode AX(12) is greater than the thickness of the second partial resistor R(2).

The first supplemental electrode AX(11) is an embedded electrode embedded at a position deeper than the first partial resistor R(1), and the second supplemental electrode AX(12) is an embedded electrode embedded at a position deeper than the second partial resistor R(2). The opposite side first supplemental electrode AX(21), the opposite side second supplemental electrode AX(12), and other supplemental electrodes are similarly embedded electrodes embedded at positions deeper than the resistor R(resistor layer). By forming a capacitor with the embedded electrodes, it is possible to reduce the number of elements necessary for the components, and it is possible to improve productivity and reduce the thickness of the resistor chip.

The above-mentioned supplemental electrodes can also be disposed on the resistor R (resistor layer) via a via electrode.

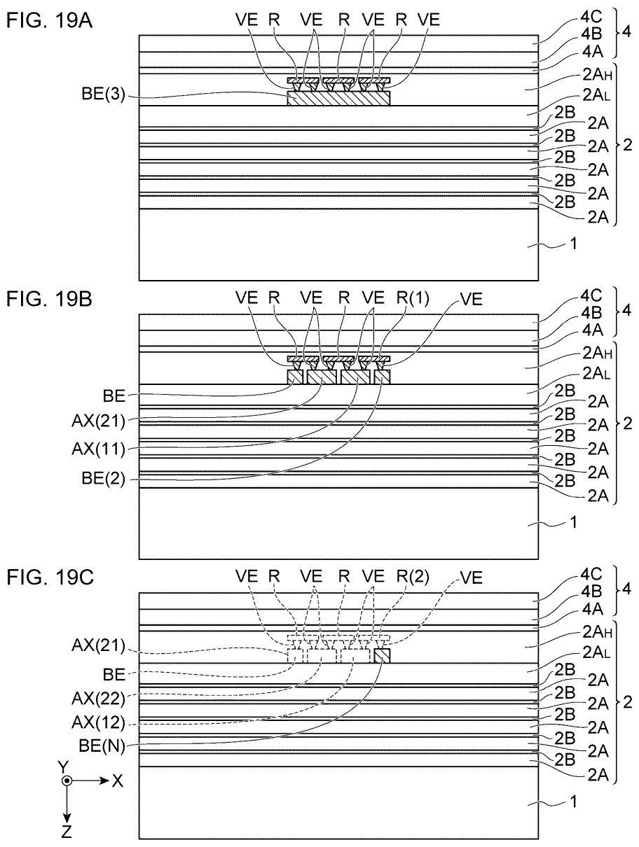

FIG. 19A is a vertical cross-sectional view of a resistor shown in FIG. 18 along the arrow A-A, FIG. 19B is vertical cross-sectional view of a resistor shown in FIG. 18 along the arrow B-B, and FIG. 19C is a vertical cross-sectional view of a resistor shown in FIG. 18 along the arrow C-C.

The structures of the insulating layer 2 and the protective film 4 are the same as those of FIGS. 16A to 16C, whereas the feature of using split resistors R and connecting the same with supplemental electrodes thereof differs from the structure shown in FIGS. 16A to 16C. This semiconductor chip includes the insulating layer 2 formed on the semiconductor substrate 1, and a resistor embedded in the insulating layer 2.

In the structure of this example, as shown in FIG. 16B, which is the cross-sectional view on the first line, the first end of the right-side first partial resistor R(1) is connected to the embedded electrode BE(2) via the via electrode VE, and the second end is connected to the first supplemental electrode AX(11) via the via electrode VE. The first end of the central first partial resistor R is connected to the first supplemental electrode AX(11) via the via electrode VE, and the second end is connected to the opposite side first supplemental electrode AX(21) via the via electrode VE. The first end of the left-side first partial resistor R is connected to the opposite side first supplemental electrode AX(21) via the via electrode VE, and the second end is connected to the opposite side embedded electrode BE via the via electrode VE.

As shown in FIG. 16C positioned slightly in the positive direction of the Y axis as compared to the cross-sectional view on the second line, the first end of the right-side second partial resistor R(2) is connected to the embedded electrode BE(N) via the via electrode VE, and the second end is connected to the second supplemental electrode AX(12) via the via electrode VE. The first end of the central second partial resistor R is connected to the second supplemental electrode AX(12) via the via electrode VE, and the second end is connected to the opposite side second supplemental electrode AX(22) via the via electrode VE. The first end of the left-side second partial resistor R is connected to the opposite side second supplemental electrode AX(22) via the via electrode VE, and the second end is connected to the opposite side embedded electrode BE via the via electrode VE.

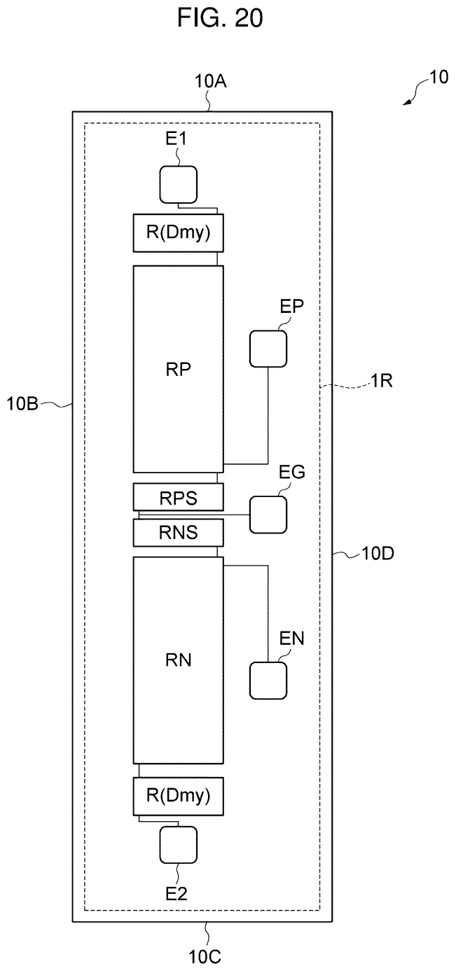

The respective supplemental electrodes are adjacent to each other in the Y axis direction and the insulating layer 2 is present therebetween. The capacitance between the supplemental electrodes can also be changed by changing the permittivity of the insulating layer 2. The capacitances of the capacitors formed by the supplemental electrodes are dependent on the sizes of the gaps, the facing areas between the supplemental electrodes, and the permittivities of the dielectrics therebetween. The range in the sizes of the gaps between the supplemental electrodes can be set so as to satisfy exemplary capacitances of the capacitors. FIG. 20 is a plan view of a resistor chip according to one example.

The resistor chip corresponds to the circuit diagram of FIG. 3A. The resistor chip 10 is configured by forming an insulating layer on a semiconductor substrate, and embedding a resistor in the insulating layer. The resistor chip 10 is rectangular in a plan view, includes a first side face 10A, a second side face 10B, a third side face 10C, and a fourth side face 10D, and an annular conductor 1R can be embedded in the insulating layer along the foregoing side faces. The annular conductor 1R can be constituted of an annular body made of a metallic material (copper, etc.), and as necessary, an annular body made of another material (e.g., resistor material CrSi) electrically connected via a via electrode (tungsten, etc.) to the top or bottom of the metallic material may be provided. The annular body can contribute to an improvement in watertightness and electrical stability.

In this example, in a plan view, the first electrode E1, the dummy resistor R(Dmy), the first high resistance unit RP, the first low resistance unit RPS, the second low resistance unit RNS, the second high resistance unit RN, the dummy resistor R(Dmy), and the second electrode E2 are arrayed along one direction. The first output electrode EP is electrically connected to the embedded electrode between the first high resistance unit RP and the first low resistance unit RPS. The second output electrode EN is electrically connected to the embedded electrode between the second high resistance unit RN and the second low resistance unit RNS. The reference electrode EG is electrically connected to the embedded electrode between the first low resistance unit RPS and the second low resistance unit RNS.

Another example of a resistor chip is also conceivable.

For example, the resistor chip corresponding to the circuit diagram of FIG. 3B has a few conceivable structures. Another example of a resistor chip structure will be described with reference to the circuit diagram of FIG. 3B and the above-mentioned resistor chip structure.

Similar to the resistor chip 10 shown in FIG. 20, the other example of the resistor chip is configured by forming an insulating layer on a semiconductor substrate, and embedding a resistor in the insulating layer. The resistor chip 10 is rectangular in a plan view, includes a first side face 10A, a second side face 10B, a third side face 10C, and a fourth side face 10D, and an annular conductor 1R can be embedded in the insulating layer along the foregoing side faces. The structure of the annular conductor 1R is as described above.

In another example of the resistor chip, in a plan view, the elements shown in FIG. 3B, or in other words, the first electrode E1, the dummy resistor R(Dmy), the high resistance unit RP2, the dummy resistor R(Dmy), the dummy resistor R(Dmy), the high resistance unit RN2, the dummy resistor R(Dmy), and the second electrode E2 are arrayed along one direction. Also, in a plan view, the high resistance unit RP1 and the dummy resistor R(Dmy) are disposed adjacent to the first electrode E1 in a direction perpendicular to the one direction. The dummy resistor R(Dmy), the high resistance unit RP1, the dummy resistor R(Dmy), the first low resistance unit RPS, the second low resistance unit RNS, the dummy resistor R(Dmy), the high resistance unit RN1, and the dummy resistor R(Dmy) are arrayed along one direction. The low voltage first end of the high resistance unit RP2 is connected to the first output electrode EP. The low voltage first end of the high resistance unit RN2 is connected to the second output electrode EN.

The low voltage first end of the first low resistance unit RPS is electrically connected to the first reference electrode EG1 via an intermediate electrode as necessary. The low voltage first end of the second low resistance unit RNS is electrically connected to the second reference electrode EG2. The first reference electrode EG1 and the second reference electrode EG2 are short-circuited in the resistor chip or an external amplifier chip, and can be used as the reference electrode EG.

The electrical connection between circuit elements of the other example of the resistor chip is as shown in FIG. 3B, but the arrangement of the circuit elements is not limited to the above example, and various modifications are possible.

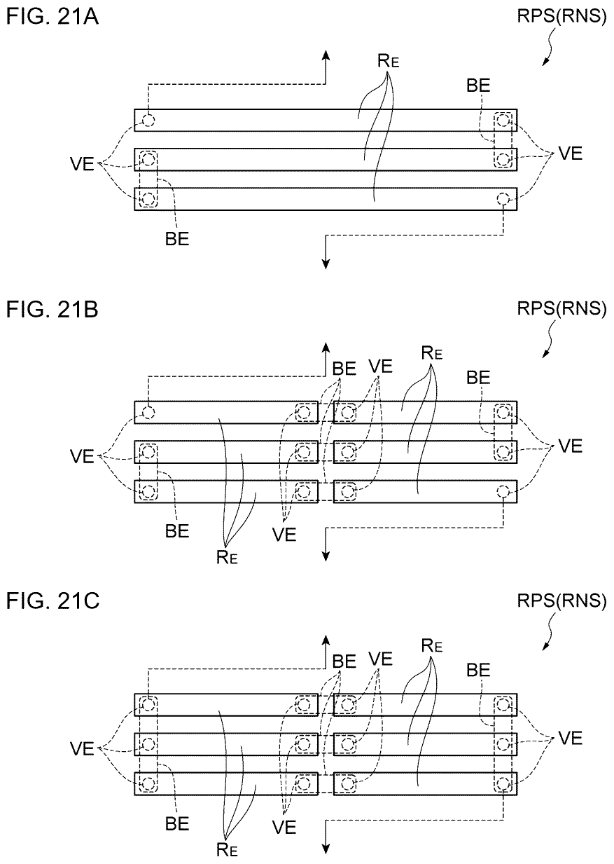

FIGS. 21A, 21B, and 21C are plan views of low resistance units for voltage detection.

The first low resistance unit RPS (or second low resistance unit RNS) includes a plurality of linear resistors R_{E} extending in a line. The via electrode VE is provided below the edge of each resistor R_{E}, and the via electrodes VE are physically and electrically connected to the embedded electrodes BE positioned therebelow. The number of linear resistors may be three or more, or less than three.

In the example shown in FIG. 21A, three linear resistors R_{E} are shown, and the first end of the linear resistor R_{E} in the first row from the top of the drawing is connected to the first end of the linear resistor R_{E} in the second row, via the via electrodes VE and the embedded electrode BE. The second end of the linear resistor R_{E} in the second row is connected to the second end of the linear resistor R_{E} in the third row, via the via electrodes VE and the embedded electrode BE.

In the example shown in FIG. 21B, the linear resistors shown in FIG. 21A are split in two in each row, such that a plurality of linear resistors R_{E} are disposed in each row. Thus, a total of six linear resistors R_{E} are shown. Opposing edges of a pair of adjacent linear resistors R_{E} in the same row are connected to each other via the via electrodes VE and the embedded electrode BE.

In the example shown in FIG. 21C, the first ends of all the linear resistors R_{E} shown in FIG. 21B are connected to each other via the via electrodes VE and a common embedded electrode BE, and the second ends of all the linear resistors R_{E} are connected to connected to each other via the via electrodes VE and a common embedded electrode BE. In this example, it is possible to achieve a lower combined resistance as compared to the resistor shown in FIG. 21B.

The vertical cross-sectional structure of the low resistance units (RPS, RNS) for detection can be made the same as the vertical cross-sectional structure of the high resistance units (RP, RN), with the exception of the plan view shape. In other words, the above-mentioned linear resistors R_{E}, the via electrode VE, and the embedded electrodes BE (embedded wiring lines) are embedded in the insulating layer formed on the semiconductor substrate.

The material of each element will be explained below.

The semiconductor substrate 1 can be conductive. The impurity concentration of the semiconductor substrate 1 may be 5×10¹³ cm⁻³ to 5×10¹⁴ cm⁻³, inclusive. The thickness of the semiconductor substrate 1 may be 50 μm to 800 μm, inclusive. The semiconductor substrate 1 can be made of silicon (Si), but a compound semiconductor such as SiC or SiGe can alternatively be used.

The material of the resistor layer (linear resistor) constituting the resistor R is a resistor material having a higher resistivity than polysilicon. Specifically, the material of the resistor (resistor layer) is a material including chromium (Cr) and silicon (Si), and is CrSi, CrSiC, or CrSiN. Other materials can be used. In other words, the material of the resistor layer constituting the resistor can specifically be made of at least one metallic compound selected from a group consisting of CrSi, CrSiN, CrSiO, TaN, and TiN. The resistor layer constituting the resistor can be formed by sputtering or the like using a target including a resistor material. Plating can also be employed depending on the type of material used for the resistor R. The material of the resistor R may be a single resistor material, but may be a combination of a plurality of resistor materials. A thickness Rd of each resistor layer constituting the resistor R can be set to 1 nm≤Rd≤5 nm. By setting the thickness Rd to less than or equal to the upper limit, the resistance can be sufficiently increased, while if the thickness Rd is set to greater than or equal to the lower limit, the durability and strength of the resistor layer can be maintained.

A metallic material such as aluminum (Al) or copper (Cu) can be used as the material for the first electrode E1, the second electrode E2, and the embedded electrode (embedded wiring line). A high melting point metal such as tungsten (W) can be used as the material for each type of via electrode, but another electrode material can also be used. Note: As described above, the various embodiments of this disclosure can be defined as follows.

[A1] A semiconductor device, including: an insulating layer 2 formed on a semiconductor substrate 1; and a resistor (first high resistance unit RP, second high resistance unit RN) embedded in the insulating layer 2, wherein the resistor includes: a first resistor layer (resistor R(1)); a first embedded electrode (BE(2)) electrically connected to a first end of the first resistor layer (resistor R(1)); a second resistor layer (resistor R(2)) disposed adjacent to the first resistor layer (resistor R(1)) and electrically connected to a second end of the first resistor layer (resistor R(1)); a second embedded electrode (BE(N)) electrically connected to a first end of the second resistor layer (resistor R(2)); a first supplemental electrode AX(11) that extends in a lengthwise direction (X axis direction) of the first resistor layer (resistor R(1)) in a plan view, that is electrically connected to the first embedded electrode (BE(2)), and that has a thickness greater than a thickness of the first resistor layer (resistor R(1)); and a second supplemental electrode AX(12) that extends in the lengthwise direction, that is electrically connected to the second embedded electrode (BE(N)), that has a thickness greater than a thickness of the second resistor layer (resistor R(2)), that is adjacent to the first supplemental electrode AX(11), and that constitutes a capacitor (C11) together with the first supplemental electrode AX(11).

[A2] The semiconductor device according to [A1], wherein a length along a lengthwise direction (X axis direction) of the first supplemental electrode AX(11) is 100 μm to 300 μm, inclusive, wherein a length along a lengthwise direction (X axis direction) of the second supplemental electrode AX(12) is 100 μm to 300 μm, inclusive, and wherein a capacitance of the capacitor (C11, etc.) is 1 fF or greater.

[A3] The semiconductor device according to [A1], wherein a length along a lengthwise direction (X axis direction) of the first supplemental electrode AX(11) is 100 μm to 300 μm, inclusive, wherein a length along a lengthwise direction (X axis direction) of the second supplemental electrode AX(12) is 100 μm to 300 μm, inclusive, and wherein a capacitance of the capacitor (C11, etc.) is 10 fF or greater.

[A4] The semiconductor device according to [A1], wherein a direction from an edge of the first resistor layer (resistor R(1)) in the lengthwise direction (X axis direction) to a center is a first direction, and wherein, in a plan view, the first supplemental electrode AX(11) extends in the first direction from a position directly above the first embedded electrode BE(2), and the second supplemental electrode AX(12) extends in the first direction from the position directly above the second embedded electrode BE(N) (FIGS. 5, 8).

[A5] The semiconductor device according to [A4], wherein, in a plan view, the first supplemental electrode AX(11) also extends in a direction opposite to the first direction from a position directly above the second embedded electrode BE(2), and the second supplemental electrode AX(12) also extends in the direction opposite to the first direction from a position directly above the second embedded electrode BE(N) (FIG. 11).

[A6] The semiconductor device according to [A1], wherein a direction from an edge of the first resistor layer in the lengthwise direction to a center is a first direction, and wherein, in a plan view, the first supplemental electrode AX(11) extends in a direction opposite to the first direction from a position directly above the second embedded electrode BE(2), and the second supplemental electrode AX(12) extends in the direction opposite to the first direction from a position directly above the second embedded electrode BE(N) (FIG. 13).

[A7] The semiconductor device according to [A1], wherein the first supplemental electrode AX(11) is continuous with the embedded electrode (BE(2)), and is a first extension section (AX) of the first embedded electrode (BE(2)) that extends in a direction opposite to the first direction, and wherein the second supplemental electrode AX(12) is continuous with the second embedded electrode BE(N), and is a second extension section (AX) of the second embedded electrode BE(N) that extends in a direction opposite to the first direction.

[A8] The semiconductor device according to [A1], further including: a dummy resistor layer (last dummy resistor layer R(f)) that is disposed adjacent to the first resistor layer (first resistor R(1)) on a side thereof opposite to the second resistor layer (second resistor R(2)), and having a first end electrically connected to the first embedded electrode BE(2); and a third resistor layer (third resistor R(3)) that is disposed adjacent to the second resistor layer (second resistor R(2)) on a side thereof opposite to the first resistor layer (first resistor R(1)), and having a first end electrically connected to the second embedded electrode BE(N).

[A9] A semiconductor device, including: an insulating layer 2 formed on a semiconductor substrate 1; and a resistor embedded in the insulating layer 2, wherein the resistor (first high resistance unit RP, second high resistance unit RN) includes, in a first line in a plan view: a plurality of first partial resistors (R) disposed separate from each other; and a first supplemental electrode AX(11) that is electrically connected to the plurality of first partial resistors (R), that has a thickness greater than a thickness of the first partial resistors (R), and that extends along the first line, wherein the resistor includes, in a second line adjacent to the first line in a plan view: a plurality of second partial resistors (R) disposed separate from each other; and a second supplemental electrode AX(12) that is electrically connected to the plurality of second partial resistors (R), that has a thickness greater than a thickness of the second partial resistors (R), and that extends along the second line, wherein the first partial resistor (R) is electrically connected to the second partial resistor (R), and wherein the first supplemental electrode AX(11) and the second supplemental electrode AX(12) constitute a capacitor (C11) (FIGS. 18, 19A-19C).

[A10] The semiconductor device according to [A9], wherein a length along the lengthwise direction (X axis) of the first supplemental electrode AX(11) is 100 μm to 300 μm, inclusive, wherein a length along the lengthwise direction of the second supplemental electrode AX(12) is 100 μm to 300 μm, inclusive, and wherein a capacitance of the capacitor C11 is 1 fF or greater (FIGS. 18, 19A-19C, 17).

[A11] The semiconductor device according to [A9], wherein a length along the lengthwise direction of the first supplemental electrode AX(11) is 100 μm to 300 μm, inclusive, wherein a length along the lengthwise direction of the second supplemental electrode AX(12) is 100 μm to 300 μm, inclusive, and wherein a capacitance of the capacitor C11 is 10 fF or greater (FIGS. 18, 19A-19C, 17).

[A12] The semiconductor device according to [A9], wherein the first supplemental electrode AX(11) is an embedded electrode embedded at a position deeper than the first partial resistors (R(1)), and wherein the second supplemental electrode AX(12) is an embedded electrode embedded at a position deeper than the second partial resistors (R(2)) (FIGS. 18, 19A-19C).

The various exemplary embodiments were described above, the invention is not limited to the exemplary embodiments, and various omissions, substitutions, and modifications may be made. Also, it is possible to combine elements of various embodiments to form another embodiment. Additionally, the various embodiments of this disclosure were described in this specification for the purpose of explanation, and it should be understood that various modifications can be made without departing from the scope and spirit of this disclosure. Thus, the various embodiments disclosed in this specification do not signify limitations to the invention, and the true scope and spirit of the invention is indicated by the attached claims.

What is claimed is:

1. A semiconductor device, comprising:
an insulating layer formed on a semiconductor substrate; and
a resistor embedded in the insulating layer,
wherein the resistor includes:
a first resistor layer;
a first embedded electrode electrically connected to a first end of the first resistor layer;
a second resistor layer disposed adjacent to the first resistor layer and electrically connected to a second end of the first resistor layer;
a second embedded electrode electrically connected to a first end of the second resistor layer;
a first supplemental electrode that extends in a lengthwise direction of the first resistor layer in a plan view, that is electrically connected to the first embedded electrode, and that has a thickness greater than a thickness of the first resistor layer; and
a second supplemental electrode that extends in the lengthwise direction, that is electrically connected to the second embedded electrode, that has a thickness greater than a thickness of the second resistor layer, that is adjacent to the first supplemental electrode, and that constitutes a capacitor together with the first supplemental electrode.

2. The semiconductor device according to claim 1,
wherein a length along the lengthwise direction of the first supplemental electrode is 100 μm to 300 μm, inclusive,
wherein a length along the lengthwise direction of the second supplemental electrode is 100 μm to 300 μm, inclusive, and
wherein a capacitance of the capacitor is 1 fF or greater.

3. The semiconductor device according to claim 1,
wherein a length along the lengthwise direction of the first supplemental electrode is 100 μm to 300 μm, inclusive,
wherein a length along the lengthwise direction of the second supplemental electrode is 100 μm to 300 μm, inclusive, and
wherein a capacitance of the capacitor is 10 fF or greater.

4. The semiconductor device according to claim 1,
wherein a direction from an edge of the first resistor layer in the lengthwise direction to a center is a first direction, and
wherein, in a plan view,
the first supplemental electrode extends in the first direction from a position directly above the first embedded electrode, and
the second supplemental electrode extends in the first direction from a position directly above the second embedded electrode.

5. The semiconductor device according to claim 4,
wherein, in a plan view,
the first supplemental electrode also extends in a direction opposite to the first direction from a position directly above the first embedded electrode, and
the second supplemental electrode also extends in a direction opposite to the first direction from a position directly above the second embedded electrode.

6. The semiconductor device according to claim 1,
wherein a direction from an edge of the first resistor layer in the lengthwise direction to a center is a first direction, and
wherein, in a plan view,
the first supplemental electrode extends in a direction opposite to the first direction from a position directly above the first embedded electrode, and
the second supplemental electrode extends in a direction opposite to the first direction from a position directly above the second embedded electrode.

7. The semiconductor device according to claim 1,
wherein a direction from an edge of the first resistor layer in the lengthwise direction to a center is a first direction,
wherein the first supplemental electrode is continuous with the first embedded electrode, and is a first extension section of the first embedded electrode that extends in a direction opposite to the first direction, and
wherein the second supplemental electrode is continuous with the second embedded electrode, and is a second extension section of the second embedded electrode that extends in a direction opposite to the first direction.

8. The semiconductor device according to claim 1, further comprising:
a dummy resistor layer that is disposed adjacent to the first resistor layer on a side thereof opposite to the second resistor layer, and having a first end electrically connected to the first embedded electrode; and
a third resistor layer that is disposed adjacent to the second resistor layer on a side thereof opposite to the first resistor layer, and having a first end electrically connected to the second embedded electrode.

9. A semiconductor device, comprising:
an insulating layer formed on a semiconductor substrate; and
a resistor embedded in the insulating layer,
wherein the resistor includes, in a first line in a plan view:
a plurality of first partial resistors disposed separate from each other; and
a first supplemental electrode that is electrically connected to the plurality of first partial resistors, that has a thickness greater than a thickness of the first partial resistors, and that extends along the first line,
wherein the resistor includes, in a second line adjacent to the first line in a plan view:
a plurality of second partial resistors disposed separate from each other; and
a second supplemental electrode that is electrically connected to the plurality of second partial resistors, has a thickness greater than a thickness of the second partial resistors, and that extends along the second line,
wherein the first partial resistor is electrically connected to the second partial resistor, and
wherein the first supplemental electrode and the second supplemental electrode constitute a capacitor.

10. The semiconductor device according to claim 9,
wherein a length along a lengthwise direction of the first supplemental electrode is 100 μm to 300 μm, inclusive,
wherein a length along the lengthwise direction of the second supplemental electrode is 100 μm to 300 μm, inclusive, and
wherein a capacitance of the capacitor is 1 fF or greater.

11. The semiconductor device according to claim 9,
wherein a length along a lengthwise direction of the first supplemental electrode is 100 μm to 300 μm, inclusive,
wherein a length along the lengthwise direction of the second supplemental electrode is 100 μm to 300 μm, inclusive, and
wherein a capacitance of the capacitor is 10 fF or greater.

12. The semiconductor device according to claim 9,
wherein the first supplemental electrode is an embedded electrode embedded at a position deeper than the first partial resistors, and
wherein the second supplemental electrode is an embedded electrode embedded at a position deeper than the second partial resistors.
